(19) United States
(12) Patent Application Publication
(10) Pub. No.: US 2005/0224842 A1
(43) Pub. Date: Oct. 13, 2005

(54) Solid-state imaging device, method for driving dolid-state imaging device, imaging method, and imager

(76) Inventor: Takayuki Toyama, Kanagawa (JP)

Correspondence Address: ROBERT J. DEPKE;LEWIS T. STEADMAN, TREXLER, BUSHNELL, GLANGLORGI, BLACKSTONE & MARR, 105 WEST ADAMS STREET, SUITE 3600, CHICAGO, IL, 60603-6299, US

(21) Appl. No.: 10/517,222

(22) PCT Filed: Jun. 12, 2003
(86) PCT No.: PCT/JP03/07496

§ 371 Date: Dec. 8, 2004

(30) Foreign Application Priority Data
Jun. 12, 2002 (JP) 2002-170986

(51) Int. Cl. H01L 27/148

(52) U.S. Cl. 257/225

(57) ABSTRACT

The present invention relates to a CCD solid state image sensor of a scanning read-out type and to a drive method thereof as well as an image pick-up method and the image pick-up device, particularly in which a plurality of vertical CCD columns can be assigned to one electric-charge detection unit with the small number of wiring. In the present invention, adjacent columns of the vertical CCDs are assigned to one electric-charge detection unit. Further, the stages of the voltage transfer between the vertical CCD column and a voltage detection unit is made different; the electrode arrangement is devised; or the drive timing is adjusted. Accordingly, the phase of electric-charge transfer with respect to the plurality of adjacent vertical CCD columns, when the horizontal electric-charge at the same position in the direction of the row obtained by the photo-conductive units is made to reach the electric-charge detection unit, becomes different.

### TECHNICAL FIELD

The present invention relates to a solid state image sensor, a drive method of the solid state image sensor, an image pick-up method and an image pick-up device.

### BACKGROUND ART

Conventionally, CCD (charge couple device) has widely been used as an electric-charge transfer unit of an image pick-up device. When the CCD is used for an image pick-up device, approximately the same number of vertical CCDs as the number of horizontal pixels and one horizontal CCD are arranged, and electric-charge is transferred from the photo-electric converter that is arranged in each pixel to the vertical CCD, the horizontal CCD and the output unit.

Lately, due to the demand for the miniaturization and the high resolution of an image in a camcorder and others, increasing the number of pixels in the same optical size is attempted so that the picture resolution of an image pick-up device is improved. However, the read-out time unavoidably increases when the number of pixels is increased. On the contrary, when all the pixels are read out during the same period of time, the clock frequency for the read-out necessarily rises, because the number of signals which must be read out in the same period of time increases.

FIG. 17 shows a conventional CCD solid state image sensor. A CCD solid state image sensor 1 shown in FIG. 17 is of an inter-line method, and a number of photo-diodes (photo-conductive units) 4 each corresponding to a pixel 3 are arranged in an image pick-up area 2 in a two-dimensional matrix shape in the vertical (column) direction and in the horizontal (row) direction. Further, in the image pick-up area 2, a plurality of vertical CCDs 5 are provided for respective columns of the photo-diodes 4, which vertically transfer the signal electric-charge e read out from each photo-diode 4 through a read-out gate 8.

Furthermore, a horizontal CCD 6 which extends in the right-left direction on the drawing is provided as one line close to each end portion in the transfer direction of the plurality of columns of vertical CCDs 5, that is, close to the last row thereof. An electric-charge detection unit 7 composed of for example a floating-diffusion amplifier FDA is provided in the end portion in the transfer direction of the horizontal CCD 6 (on the left side of the drawing). The electric-charge detection unit 7 converts a signal electric-charge input in order from the horizontal CCD 6 into a pixel signal voltage to be output. An image signal S is obtained by outputting the pixel signal voltage in time series.

FIG. 18 is a schematic view of a timing chart of a transfer pulse which drives the conventional solid state image sensor 1. The signal electric-charge obtained by the photo-electric conversion in the photo-diode 4 corresponding to the pixel 3 in the image pick-up area 2 is read out to the vertical CCD 5 through the read-out gate 8. Driven by for example the vertical transfer pulses φV1 to φV4 used for the four-phase drive, the vertical CCD 5 transfers the signal electric-charge e that is read out to the vertical CCD 5 to the horizontal CCD 6 with a plurality of rows in parallel. The horizontal CCD 6 is driven by the horizontal transfer pulses φH1 and φH2 used for two-phase drive and further transfers the signal electric-charge e transferred from the vertical CCD 5 to the electric-charge detection unit 7. Thus, the signal electric-charge e is converted into the image signal S in time series and is output from the electric-charge detection unit 7.

At this time, as shown in FIG. 18, when a period of time that the signal electric-charge e obtained in the photo-diode 4 is transferred to the horizontal CCD 6 through the vertical CCD 5 and a period of time that the signal electric-charge e transferred to the horizontal CCD 6 is transferred to the electric-charge detection unit 7 through the horizontal CCD 6 are compared, the latter is overwhelmingly longer. Specifically, the time required to read out the signal electric-charge e of all the pixels 3 is limited by the transfer speed of the horizontal CCD 6. That is, the clock frequency of the horizontal CCD 6 is the highest in the solid state imaging device, and the restriction thereof becomes one of the key points for obtaining the high density pixels.

Further, an increase in the number of pixels in the same optical size causes a problem that the area of the sensor portion per one pixel decreases, consequently which causes a problem of the decline of sensitivity.

A limit on this clock frequency and the sensitivity decline per one pixel are the limitation factors for the increase of the pixel numbers in the CCD solid state image sensor which is the mainstream of the solid state image sensor of late. This fact is explained specifically in the followings.

As a read-out method in which the clock frequency of the horizontal CCD is reduced, mainly two kinds of method have been devised. The first method is a method proposed in the Japanese Patent No. 2785782 and Japanese Published Patent Application 2001-119010 for examples, in which the sensor portion of the solid state image sensor is divided into a plurality of blocks and electric-charge is transferred by the horizontal CCD of each block. Hereinafter, the first method is called a “plurality of horizontal CCDs read-out method”.

The second method is a method proposed in Japanese Published Patent Application H6-97414 and Japanese Patent No. 3057898 for examples, in which an electric-charge detection unit such as a floating-diffusion amplifier FDA or the like is provided for each vertical CCD, a signal electric-charge is converted into a voltage signal in this electric-charge detection unit, and the voltage signal of each vertical CCD is sequentially output to an output unit by the switch selection. Hereinafter, the second method is called a “scanning read-out method”.

Hereupon, further consideration is given to the above-mentioned two read-out methods. Considering the “plurality of horizontal CCDs read-out method” first, the horizontal CCD is divided into the plurality of blocks, and the data rate apparently improves by outputting the plurality of outputs in parallel. Accordingly, the clock frequency of the horizontal CCD can be reduced.

However, since the electric-charge detection unit in which a signal electric-charge is converted into the pixel signal is divided into a plurality of portions, the density unevenness occurs in the signal level which is output by each block and the seam portion between the blocks becomes discontinuous due to the difference of the conversion gain in the divided electric-charge detection units. Since the whole of the picture is divided into the plurality of blocks, this density unevenness appears on the image as a thick stripe pattern and the stripe pattern (density unevenness) can be visible because of comparatively low frequency.

Further, basically the read-out method remains unchanged from a conventional CCD type image sensor, and a serial output is performed with respect to one block. In the future, in order to compensate for the decline in sensitivity caused by the high density pixels, the signal compensation with an adding method in which the signal of the same color in the same line (row) is mixed with each other is considered to be important; however, the selectivity of the image signal of the “plurality of horizontal CCDs read-out method” is extremely small, because basically the method is of the serial output. Therefore, the decline in sensitivity caused by the high density pixels may not be compensated with signal correction.

Next, when considering the “scanning read-out method”, as indicated in Japanese Published Patent Application H6-97414, an electric-charge detection unit such as a floating-diffusion amplifier FDA is provided corresponding to each column CCD or to plurality of column CCDs. In this case, the density unevenness in the electric-charge detection unit caused by the difference in the conversion gain becomes invisible on the picture due to comparatively high frequency, which is not a problem; however, the reset dispersion among the electric-charge detection units becomes a problem. In order to eliminate the reset dispersion, it is desirable to provide a CDS (Correlated Double Sampling) circuit subsequent to the electric-charge detection unit, for example. Considering the size of the CDS circuit (most part of the CDS circuit area is the capacity of several pF), a method in which the number of CDS circuits can be reduced is desirable.

In this case, a first method in which an output signal from the electric-detection unit provided in each column CCD is input to one CDS circuit by a switch selection, and a second method in which one electric-charge detection unit is provided corresponding to a plurality of column CCDs and one CDS circuit is provided with each electric-charge detection unit are considered.

However, though the number of CDS circuits decreases in the first method, the processing frequency in the CDS circuit portion is equal to the clock frequency of the horizontal CCD, which becomes a problem with respect to the high density pixels. In other words, the problem of the high clock frequency is only passed on to the CDS circuit from the horizontal CCD. In view of the above, the second method in which one electric-charge detection unit is provided corresponding to a plurality of column CCDs is more desirable.

However, in the second method, a selective gate VOG (read-out gate) which selects the plurality of column CCDs for reading out the signal electric-charge must be provided between the vertical CCD and the electric-charge detection unit. Providing the selective gate between the vertical CCD and the electric-charge detection unit is possible when considering the “scanning read-out method” about an equivalent circuit as shown in FIG. 19A; however, wiring of a selection wire to the read-out gate becomes a problem when the actual pattern is considered.

Specifically, as shown in FIG. 19B, when four columns CCD 11 is assigned to one electric-charge detection unit 12, the outside columns A and D can be patterned with the selection wire led to the selective gates 13A and 13D; however, there is no space for the inside columns B and C which exist in the center, and it is difficult to form as an actual pattern the selection wire led to the selective gates 13B and 13C shown with a slant lines. Patterning may be considered to perform on the floating-diffusion FD; however, a problem of noise occurrence is newly caused.

As described above, a problem of sensitivity decline and the decrease in the clock frequency of the horizontal CCD caused by increasing the pixel density remains unsolved in the conventional CCD solid state image sensor.

### DISCLOSURE OF THE INVENTION

The present invention aims to provide a CCD solid state image sensor in which both the clock frequency and the sensitivity can be improved, a method for driving the CCD solid state image sensor, and an image pick-up method and an image pick-up device which use the CCD solid state image sensor.

A first solid state image sensor according to the present invention includes: a plurality of photo-conductive units which are arranged in each direction of the row and the column in the two-dimensional shape and which obtain a signal electric-charge by receiving light, a column electric-charge transfer unit which transfers a signal electric-charge obtained by the photo-conductive unit in the column direction, an electric-charge detection unit which is provided for every plurality of adjacent columns and which converts the signal electric-charge transferred from the column electric-charge transfer unit into a pixel signal, and a dummy electric-charge transfer unit arranged between the column electric-charge transfer unit and the electric-charge detection unit, in which the number of stages of the electric-charge transfer is made different with respect to each of the plurality of columns.

In the above first solid state image sensor, it is desirable that an electrode for the vertical transfer drive is shared with the plurality of adjacent column electric-charge transfer units.

Further, the electric-charge detection unit can be provided for every two adjacent columns. In this case, the dummy electric-charge transfer unit makes the phase of the electric-charge transfer, when the signal electric-charge of the photo-conductive unit in the same row direction reaches the electric-charge detection unit, different by 180 degrees inverted in the number of stages of electric-charge transfer.

A second solid state image sensor according to the present invention includes a plurality of photo-conductive units which are arranged in each direction of the row and the column in the two-dimensional shape and which obtain a signal electric-charge by receiving light, a column electric-charge transfer unit which transfers a signal electric-charge obtained by the photo-conductive unit in the column direction, and an electric-charge detection unit provided in every plurality of adjacent columns and which converts the signal electric-charge transferred by the column electric-charge transfer unit into a pixel signal. Further, an electrode used for a vertical transfer drive is formed such that in the case where a common vertical transfer control signal is applied to the plurality of adjacent columns, phases of electric-charge transfer when the signal electric-charge at the same position in the row direction obtained in the photo-conductive units reaches the electric-charge detection unit are made different.

In the first or the second solid state image sensor according to the present invention, the electric-charge detection unit is preferably provided with a floating diffusion (floating diffusion layer) on the input side of the signal electric-charge. Further in this case, it is desirable to have a read-out gate on the input side, which is shared with the plurality of adjacent columns to read out the signal electric-charge. Further, a wiring to the read-out gate may be shared with a wiring to the read-out gate for the other adjacent electric-charge detection units.

Thus, the above-mentioned first and second solid state image sensors may be required to be formed including a plurality of photo-conductive units, a column electric-charge transfer unit which transfers the signal electric-charge obtained by the photo-conductive unit in the column direction and a electric-charge detection unit which is provided for each column and which converts the signal electric-charge transferred by the column electric-charge transfer unit into the pixel signal; in which when the common vertical transfer control signal is applied to the plurality of adjacent columns, the phases of the electric-charge transfer are different when the signal electric-charge at the same position in the row direction obtained by the photo-conductive units reaches the electric-charge detection unit.

Then, as a specific means to realize the above, the first solid state image sensor uses a dummy electric-charge transfer unit in which the number of stages of the electric-charge transfer is different, and the second solid state image sensor uses the configuration in which the formation of the vertical transfer electrode to which the vertical transfer control signal (transfer pulse) is applied is correspondingly made.

A third solid state image sensor according to the present invention, which is obtained with the different viewpoint from the above-mentioned first and second solid state image sensors, includes: a plurality of photo-conductive units which are arranged in each direction of the row and the column in the two-dimensional shape and which obtain a signal electric-charge by receiving light, a column electric-charge transfer unit which transfers the signal electric-charge obtained by the photo-conductive unit in the column direction, and a electric-charge detection unit which is provided in every two adjacent columns and which converts the signal electric-charge transferred by the column electric-charge transfer unit into a pixel signal. Further, a selective gate is provided independently on the input side of the electric-charge of the electric-charge detection unit for each of the two adjacent columns to read out the signal electric-charge.

In the first, second and third solid state image sensors according to the present invention, each electric-charge detection unit may include a reset gate in the electric-charge detection unit to be initialized after converting the signal electric-charge into the pixel signal.

Alternatively, it is desirable that a differential detection unit which detects the difference between the output without the signal electric-charge and the signal level with the signal electric-charge in the pixel signal is provided subsequently to the electric-charge detection unit.

Further, it is desirable to provide a plurality of electric-charge detection units for the plurality of adjacent columns in the column direction with a plurality of adjacent columns as a group and to provide a horizontal scanning unit subsequent to the plurality of electric-charge detection units, which selects and outputs the pixel signals output from each of the plurality of electric-charge detection units sequentially in time series in the row direction.

A drive method of the solid state image sensor according to the present invention is the drive method which drives the first, second or third solid state image sensor according to the present invention, in which pixel signals with respect to a plurality of adjacent columns are each driven to be output with a different phase in the transfer of the signal electric-charge in the column direction.

Further, for example, in the case where the electric-charge detection unit includes a selective gate to read out the signal electric-charge and a reset gate to be initialized after converting the signal electric-charge into the pixel signal, when the selective gate is off, the reset gate is turned on, so that the plurality of adjacent columns can be read out sequentially.

An image pick-up method according to the present invention is the image pick-up method, in which an image signal is obtained using the first, second or third solid state image sensor, and first, the pixel signals with respect to the plurality of adjacent columns are obtained with different phases in the transfer of the signal electric-charges in the column direction. Next, the image signal with respect to each different phase is obtained by selecting the obtained pixel signals sequentially in time series in the row direction. Finally, the image signal sequentially aligned in the row direction is obtained by rearranging the pixel signals of the image signal in the row direction in accordance with the order of the plurality of columns.

An image pick-up device according to the present invention is the image pick-up device which obtains an image signal using the first, second or third solid state image sensor, and includes a horizontal scanning unit which obtains an image signal with respect to each of the different phases by sequentially selecting the pixel signals, which is output from the solid state image sensor with a different phase in the transfer of the signal electric-charges in the column direction, in time series in the row direction, and a row adjustment unit which obtains the image signal sequentially aligned in the row direction by rearranging the pixel signals of the image signal that is output from the horizontal scanning unit in the row direction in accordance with the order of the plurality of columns.

With respect to the first solid state image sensor, one electric-charge detection unit is assigned to a plurality of columns, and a dummy electric-charge transfer unit is provided between the column electric-charge transfer unit and the electric-charge detection unit. Accordingly, various electrodes and gates such as a vertical transfer electrode and an electrode used for the selective gate can be shared with the plurality of columns.

With respect to the second solid state image sensor, one electric-charge detection unit is assigned to a plurality of columns, and an electrode used for a vertical transfer drive is formed such that phases of electric-charge transfer, when the signal electric-charge of the photo-conductive units in the same row reaches the electric-charge detection unit, are different with respect to the plurality of adjacent column electric-charge transfer units. Accordingly, various electrodes and gates such as a vertical transfer electrode and an electrode used for the selective gate can be shared with respect to the plurality of columns.

With respect to the third solid state image sensor, one electric-charge detection unit is assigned to every two columns, and a selective gate to read out a signal-charge is provided independently on the input side of the signal electric-charge in the electric-charge detection unit for each of the two columns. Accordingly, the problem of wiring of the selective wire to the selective gate is resolved.

In the drive method according to the present invention, the pixel signals with respect to a plurality of adjacent columns are driven to be output with different phases in the vertical transfers. Further, according to the image pick-up method and image pick-up device of the present invention, the image signal is obtained with respect to each phase by sequentially selecting in the row direction in time series the pixel signals obtained with the different phases in the vertical transfers. Then, image picture information on the image pick-up area and the image signals are made to have the same arrangement by rearranging the pixel signals in the row direction in accordance with the order of alignment of vertical columns.

As described above, the solid state image sensor (the first and second solid state image sensors, for example) according to the first embodiment of the present invention was formed such that the phases of the electric-charge transfers when the signal electric-charges at the same position in the direction of the row obtained by the photo-conductive units reach the electric-charge detection unit are made different, after assigning the plurality of adjacent columns to one electric-charge detection unit, making the number of stages of the vertical transfer to the electric-charge detection unit become different, devising an arrangement of the electrode, adjusting the drive pulse timing or performing other operations. Accordingly, a selective gate VOG is not required to be provided independently with respect to a plurality of columns, and the restriction in wiring decreases greatly, and a space for such as a CDS circuit of the subsequent stage can be secured.

Furthermore, in the solid state image sensor (the third solid state image sensor, for example) according to the second embodiment of the present invention, that is, in the configuration in which the two columns are assigned to one electric-charge detection unit and a selection mechanism (the selective gate) which controls the electric-charge transfer from the columns is provided independently, though the number of wiring to the selective gate is larger than the first embodiment, the wiring space for the selective gate in the center portion does not become a problem.

As described above, in the solid state image sensor of the present invention, since signals in the horizontal direction are obtained by using the common vertical transfer electrode for respective columns and by using the common selective gate for the plurality of columns to reduce the restriction in the wiring and to sequentially select and rearrange in the horizontal direction the pixel signals of each column which are converted in the electric-charge detection unit, the image signal corresponding to the signal electric-charge can be obtained without employing the electric-charge transfer unit in the horizontal direction (such as a horizontal CCD).

Since the electric-charge transfer unit used in the horizontal direction is not employed, the problem that the horizontal clock frequency becomes a limit when the number of pixels of a solid state image sensor increases can be resolved.

Since a signal can be read by each column, the sensitivity decline per one pixel caused by the high density pixels can be compensated using a signal of adjacent pixels (or, the same color pixel which is positioned by two pixels apart).

### BRIEF DESCRIPTION OF DRAWINGS

FIG. 1 is a schematic constitutional view showing a first embodiment of an image pick-up device which uses a CCD solid state image sensor according to the present invention;

FIG. 2 is a schematic plan view showing the vicinity of the boundary portion between the vertical CCD and the read-out processing unit according to the CCD solid state image sensor of the first embodiment of the present invention;

FIG. 3 is a sectional view schematically showing the vicinity of the boundary portion between the vertical CCD and the read-out processing unit according to the CCD solid state image sensor of the first embodiment of the present invention;

FIG. 4 is a schematic view of a timing chart of vertical transfer pulses φV1 to φV6 which drive the vertical CCD and the dummy vertical CCD, according to the CCD solid state image sensor of the first embodiment of the present invention;

FIG. 5 is a diagram which explains the relationship between the vertical transfer electrode constituting the vertical CCD and the dummy vertical CCD, and the vertical transfer pulses φV1 to φV6 which are applied thereto according to the CCD solid state image sensor of the first embodiment of the present invention;

FIG. 6 is a diagram which explains the relationship between the vertical transfer pulses φV1 to φV6 which drive the vertical CCD and the dummy vertical CCD, and the electric-charge transfer according to the CCD solid state image sensor of the first embodiment of the present invention;

FIG. 7 is a schematic view of a timing chart of the vertical transfer pulses φV1 to φV6, which explains an example of making the electric-charge transfer into a reverse phase by changing the arrangement of the vertical transfer electrode;

FIG. 8A is a diagram which shows the relationship between the vertical transfer electrode and the vertical transfer pulses φV1 to φV6 applied thereto to explain an example of making the electric-charge transfer into a reverse phase by changing an arrangement of the vertical transfer electrode; and FIG. 8B is a schematic view of the patterning on the vertical transfer electrode;

FIG. 9 is a diagram which explains the relationship between the vertical transfer pulse and the electric-charge transfer;

FIG. 10A is a circuit diagram showing a first example of the structure for one unit in a read-out processing unit; and FIG. 10B is a diagram showing each signal waveform;

FIG. 11 is a circuit diagram showing a second example of the structure for one unit in the read-out processing unit;

FIG. 12A is a block diagram showing an example of the whole configuration of an image pick-up device including a signal processing circuit connected to the stage subsequent to the read-out processing unit; and FIG. 12B is a block diagram showing the relevant part thereof;

FIG. 13 is a diagram which explains a first modified example of the CCD solid state image sensor according to the first embodiment of the present invention;

FIG. 14 is a diagram which explains a second modified example of the CCD solid state image sensor according to the first embodiment of the present invention;

FIG. 15 is a diagram which explains a modified example when the first embodiment of the CCD solid state image sensor is driven by four-phase drive;

FIG. 16A is a circuit diagram of the relevant part which explains the CCD solid state image sensor of the third embodiment of the present invention; and FIG. 16B is a schematic plan view thereof;

FIG. 17 is a constitutional diagram showing a conventional CCD solid state image sensor;

FIG. 18 is a schematic view of a timing chart of the transfer pulse which drives the conventional CCD solid state image sensor; and

FIG. 19A is a circuit diagram of the relevant part which explains a problem of “the scanning read-out method” of the conventional type; and FIG. 19B is a schematic plan view thereof.

### BEST MODE FOR CARRYING OUT THE INVENTION

Hereinafter, embodiments of the present invention will be explained in detail with reference to the drawings.

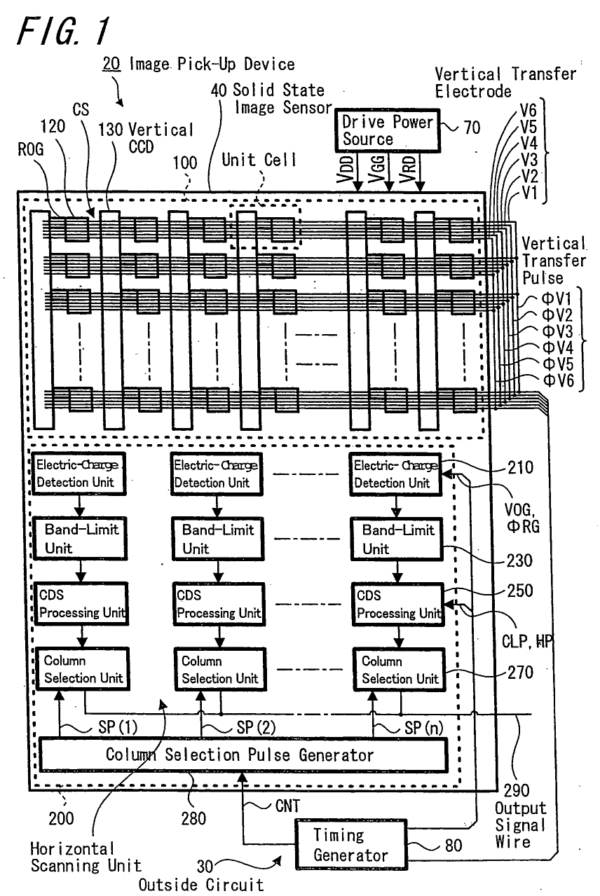

FIG. 1 is a schematic constitutional view showing a first embodiment of an image pick-up device which uses a CCD solid state image sensor according to the present invention and showing the case in which the present invention is applied to a CCD area sensor of an inter-line transfer method.

As shown in FIG. 1, an image pick-up device 20 includes a CCD solid state image sensor 40 having an image pick-up area 100 and a read-out processing unit 200 arranged on the lower side in the drawing with respect to the image pick-up area 100, and an outside circuit 30 which drives the CCD solid state image sensor 10.

The outside circuit 30 includes a drive power source 70 which supplies to the CCD solid state image sensor 40 a desired drive voltage such as a drain voltage V_{DD}, a gate voltage V_{GG} or a reset-drain voltage V_{RD}, and a timing generator 80 (TG) which generates various pulse signals such as the vertical transfer pulses φV1 to φV6, a read-out pulse X_{SG}, a selective gate voltage (a fixed voltage) V_{OG}, a reset gate pulse φRG, a clump pulse CLP, a hold pulse HP and others which drive the CCD solid state image sensor 40, or a control signal CNT and others with respect to a column selection pulse generator 280.

The CCD solid state image sensor 40 which constitutes the image pick-up device 20 is formed such that a number of photo-conductive units (sensor units; photo cells) 120 composed of a PN junction photo diode as an example of a sensor corresponding to a pixel (unit cell) are arranged on the semiconductor substrate in the vertical (column) direction and in the horizontal (row) direction in the two-dimensional matrix shape. Those photo-conductive units 120 convert the incident light entered from the light receiving surface into the signal electric-charge in accordance with the amount of light to be stored.

Further, in the CCD solid state image sensor 40 a vertical CCD 130 which is an example of the column electric-charge transfer unit having a plurality of vertical transfer electrodes V1 to V6 (six per unit sell in this embodiment) corresponding to the six-phase drive in each column of the photo-conductive unit 120 is provided. The vertical transfer electrodes V1 to V6 almost extend straight in the row direction on the drawing with respect to the adjacent vertical CCDs 130 in the image pick-up area 100 so that the signal electric-charges of the photo-conductive units 120 in the same row are transferred with the same phase to the electric-charge detection unit 210.

The image pick-up area 100 includes a number of photo-conductive units 120 arranged in the two-dimensional matrix shape, and a plurality of vertical CCDs 130 which are provided for each column of those photo-conductive unit 120 and which vertically transfer the signal electric-charge read out from each photo-conductive unit 120 through the read-out gate (not shown in the drawing).

Each of the vertical transfer electrodes V1 to V6 sets a repetition unit in a transfer direction in every one pixel (in other words, unit cell) of the photo-conductive unit 120. The transfer direction is a vertical direction in the drawing, and the vertical CCDs 130 are provided in this direction. Further, a read-out gate portion (transfer gate) ROG exists between those vertical CCDs 130 and respective photo-conductive units 120. Furthermore, a channel stop (element isolation layer) CS is provided in the boundary portion of each unit cell. Further, the read-out processing unit 200 is provided close to each end portion in the transfer direction of the vertical CCDs 130 of the plurality of columns, namely close to the last row of the vertical CCDs 130.

The read-out pulse X_{SG} sent from the timing generator 80 constituting the outside circuit 30 is applied to a gate terminal electrode of the read-out gate unit ROG, so that a electric potential under that gate terminal electrode becomes deep and the signal electric-charge stored in each of the photo-conductive units 120 is read out to the vertical CCD 130 through the relevant read-out gate unit ROG. The signal electric-charge read out to the vertical CCD 130 is sequentially transferred to the read-out processing unit 200 along the column with the vertical transfer pulses φV1 to φV6 of the fixed timing being applied to the vertical transfer electrodes V1 to V6 (called six electrodes/six-phase drive).

The read-out processing unit 200 includes an electric-charge detection unit 210 which receives and converts signal electric-charge which is input sequentially from the vertical CCD 130 into a voltage signal, a band-limit unit 230 which restricts the frequency bandwidth of the voltage signal converted by the electric-charge detection unit 210, a CDS processing unit 250 which suppresses the reset noise occurred at the electric-charge detection unit 210, and a column selection unit 270 which selects the column of the voltage signal output from the CDS processing unit 250 to be output. Further, the read-out processing unit 200 includes a column selection pulse generator 280 which generates a column selection pulse (horizontal scanning pulse) SP(n) which defines the scanning in the horizontal direction and supplies the result to a column selection unit 270.

Hereupon, this first embodiment is characterized in that the electric-charge detection unit 210, the band-limit unit 230, the CDS processing unit 250 and the column selection unit 270 are provided for every two adjacent columns. In other words, with respect to one set of two adjacent columns in the horizontal direction, the electric-charge detection unit 210 and others are correspondingly provided respectively in the image pick-up area 100 where a plurality of pixel lines including a photo-conductive unit 120 column composed of a plurality of photo diodes and a vertical CCD 130 connected to each photo-conductive unit 120 through each read-out gate unit ROG are arranged in parallel. Though an example in which two columns are made to one set is here used, it is not specially restricted to this value as described in the other embodiments later on.

In the read-out processing unit 200, the electric-charge detection unit 210 stores the signal electric-charge, which is sequentially input from the vertical CCD 130 in the image pick-up area 100, in the floating diffusion that is not shown, and the signal electric-charge which is converted into the voltage signal under the controls of the selective gate voltage V_{OG} and that of the reset gate pulse φRG supplied from the timing generator 80 is output as the pixel signal (CCD output signal) through the output circuit of, for example, the source-follower type that is not shown.

After converted into the voltage signal by the electric-charge detection unit 210, the frequency bandwidth of the pixel signal is restricted by the band-limit unit 230, and then, the reset noise occurred in the electric-charge detection unit 210 is suppressed by the CDS processing unit 250. The column selection unit 270 outputs the voltage signal from the CDS processing unit 250 to the output signal wire 290, when the column selection pulse SP(n) supplied from the column selection pulse generator 280 is in active.

In other words, the voltage signal with respect to each of the odd column and even column in the vertical direction is sequentially selected by the column selection unit 270 in the horizontal direction and is read out respectively regarding each of the odd column and the even column (by the time sharing), so that the image signal with respect to each of the odd column and the even column having a different phase is obtained. Namely, the horizontal scanning unit according to the present invention is composed of the picture reproduction means 270 and the column selection pulse generator 280.

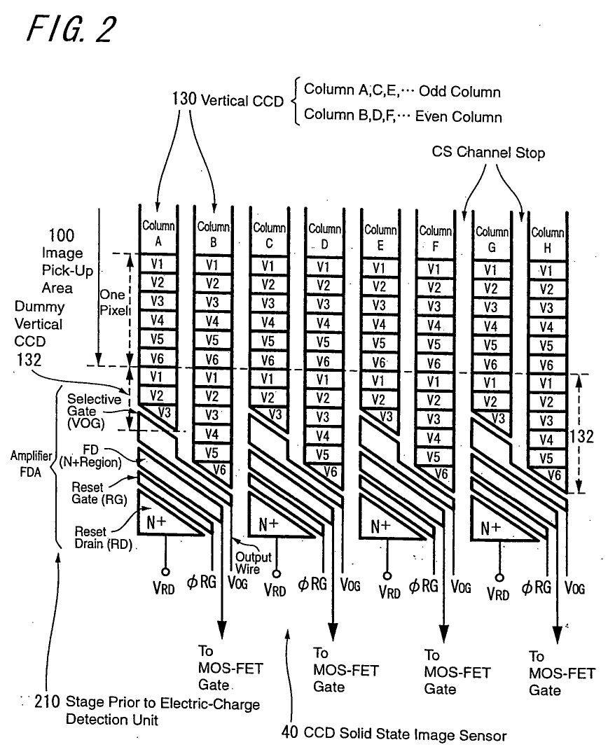

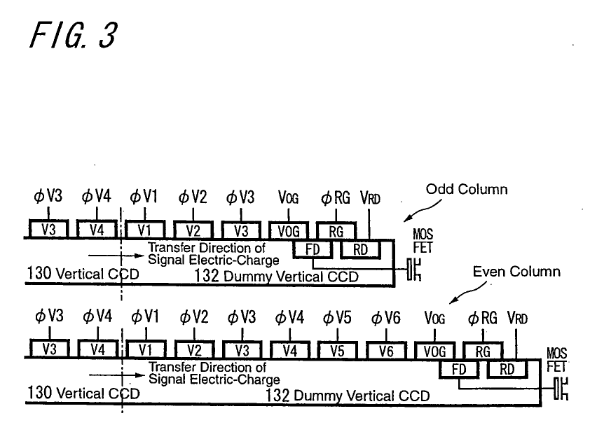

FIGS. 2 and 3 are drawings which show the vicinity of the boundary portion between the vertical CCD 130 and the read-out processing unit 200 in the CCD solid state image sensor 40 of the first embodiment. FIG. 2 is a schematic plan view and FIG. 3 is a schematic vertically-sectional view in the direction of the column.

As shown in the drawings, an amplifier FDA of the floating diffusion type is provided on the side of the vertical CCD 130 which is the stage prior to the electric-charge detection unit 210. In other words, the amplifier FDA includes a selective gate VOG, a floating diffusion FD which is the N+ region, a reset gate wire RG, a reset drain RD which is the N+ region and others. One electric-charge detection unit 210 is respectively provided corresponding to two adjacent columns of the odd columns A, C, E . . . and the even columns B, D, F . . . of the vertical CCDs 130.

A plurality of vertical transfer electrodes (six vertical transfer electrodes V1 to V6 per one pixel in this embodiment) are formed above the vertical CCD 130, and a channel stop CS is formed between respective columns, in which the photo-conductive unit 120 not shown and the read-out gate unit ROG are provided.

A dummy vertical CCD 132 which is an example of the dummy electric-charge transfer unit is provided between the selective gate VOG side of the electric-charge detection unit 210 and the vertical CCD 130 in the image pick-up area 100. The dummy vertical CCD 132 is covered with a shade coating. With respect to the length of the dummy vertical CCD 132, namely with respect to the number of stages of the dummy vertical transfer electrode, the odd column has three stages corresponding to the transfer electrodes V1 to V3, and the even column has six stages of V1 to V6. In other words, the length of the vertical CCD including the whole of the vertical CCD 130 and the dummy vertical CCD 132 (the number of stages of the registers corresponding to the electrodes) is different only by three stages for the register.

The vertical transfer pulses φV1 to φV6 each having a timing described later on are sequentially applied to the transfer electrodes V1 to V6 of the vertical CCD 130 and to the transfer electrodes V1 to V6 of the dummy vertical CCD 132 in common.

With respect to the length of the dummy vertical CCD 132, namely with respect to the number of stages of the dummy vertical transfer electrode, three stages of V1 to V3 are provided for the odd column, and six stages of V1 to V6 are provided for the even column. Thus, even if the same vertical transfer pulses 100 V1 to φV6 are applied to both the odd columns and even columns, the transfer phase (read-out phase) of the signal electric-charge from the vertical CCD 130 to the electric-charge detection unit 210 is shifted by 180 degrees, and the electric-charge reaches the electric-charge detection unit 210 (the floating diffusion FD in this embodiment) at different timing.

In other words, the length of the dummy vertical CCD 132 (the number of stages of the electric-charge well) connected to the floating diffusion FD is changed, and by shifting the electric-charge transfer phase by 180 degrees between the vertical CCDs 130 of two columns when reaching the floating diffusion FD, the signal electric-charge of the vertical CCDs 130 of two columns can be transferred to one floating diffusion FD with a single selective gate VOG to the floating diffusion FD, instead of using two selective gates VOG for each vertical CCD for selecting the vertical CCD 130. As a result, the number of wiring connected to the gate can be reduced in comparison with “the scanning read-out method” of the conventional type and the sensor area can be used efficiently.

Note that the number of stages of the dummy vertical CCD 132 is not limited to that of the example shown in the drawing and can be changed appropriately such that the signal electric-charge of each column is made to reach the electric-charge detection unit 210 (the floating diffusion FD in this embodiment) with different phase (timing) in one cycle of the transfer in accordance with: the number of phases, the number of the transfer electrodes, the number of columns for one electric-charge detection unit 210 and others. Further, in the example shown in the drawing, the relation of “Db=Da+3” is only required between the number of stages Da of the odd column and the number of stages Db of the even column such as 0 stage for odd column and three stages for even column, removing the common portion of V1 to V3 with respect to the odd column and the even column, for example. Further, the relation between the odd column and the even column can be reversed such as “Da=Db+3”.

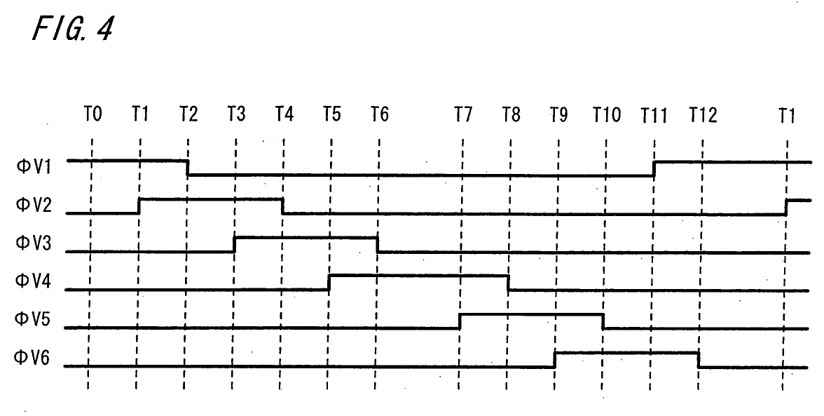

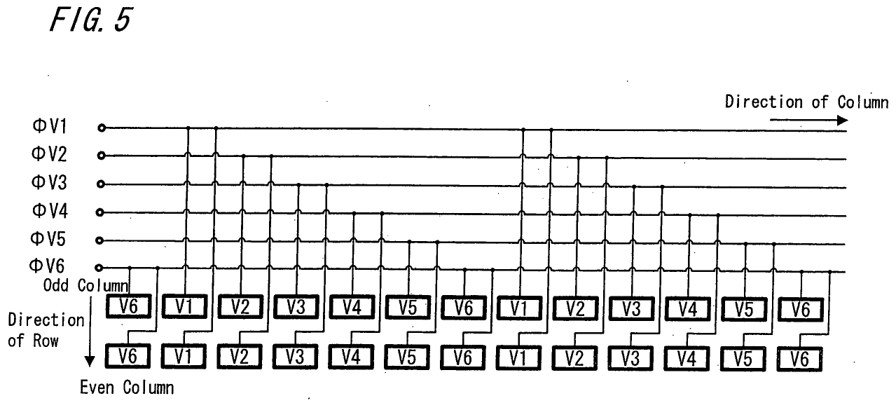

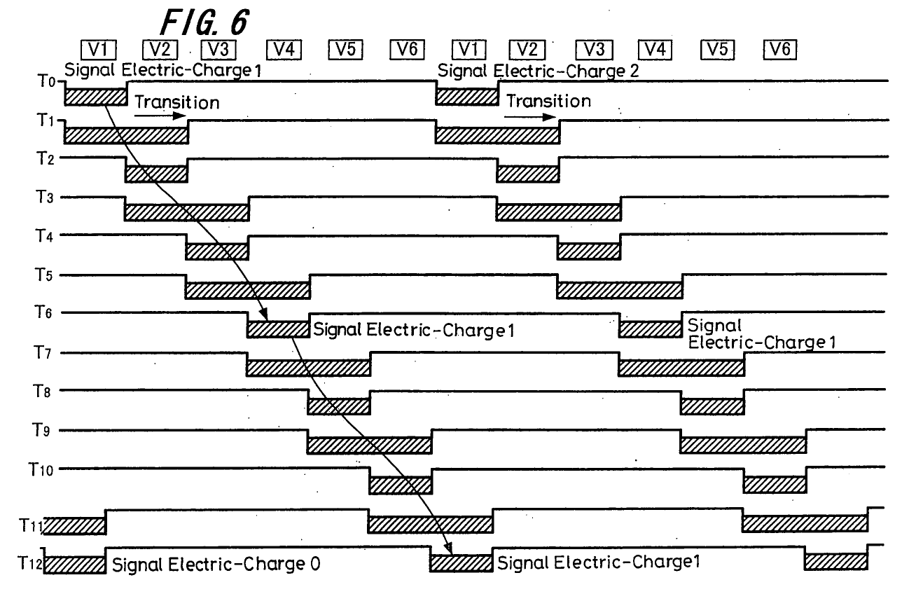

FIGS. 4 to 6 are drawings explaining the relationship between the vertical transfer pulses φV1 to φV6 which drive the vertical CCD 130 and the dummy vertical CCD 132 and the electric-charge transfer in the CCD solid state image sensor 40 of the first embodiment. Hereupon, FIG. 4 is a basic-type timing chart of the vertical transfer pulses φV1 to φV6 of the six-phase drive. FIG. 5 is a schematic view showing the relationship between the transfer electrodes V1 to V6 of the odd column and even column in the vertical CCD 130 and in the dummy vertical CCD 132 and the vertical transfer pulses φV1 to φV6 applied thereto. Further, FIG. 6 is a schematic view showing the relationship between a voltage potential in the vertical CCD 130 and in the dummy vertical CCD 132 shown in FIG. 5 and the electric-charge transfer.

As described above, the register (electric-charge well; charge packet) corresponding to respective transfer electrodes V1 to V6 of the vertical CCD 130 and the dummy vertical CCD 132 is driven by the vertical transfer pulses φV1 to φV6 shown in FIG. 4 in common.

As shown in FIG. 5, in the electrode structure in which six transfer electrodes V1, V2, V3, V4, V5 and V6 are repeatedly arranged in order from the left side on the drawing, the first phase vertical transfer pulse φV1 to the transfer electrode V1, the second phase vertical transfer pulse φV2 to the transfer electrode V2, the third phase vertical transfer pulse φV3 to the transfer electrode V3, the fourth phase vertical transfer pulse φV4 to the transfer electrode V4, the fifth phase vertical transfer pulse φV5 to the transfer electrode V5 and the sixth phase vertical transfer pulse φV6 to the transfer electrode V6 are applied, respectively. Then, as shown in FIG. 6, when the vertical transfer pulses φV1 to φV6 are turned on and a high voltage is applied to each of the transfer electrodes V1 to V6, the electric potential under the corresponding transfer electrode becomes deep to form a charge packet. Further, when the vertical transfer pulses φV1 to φV6 are turned off and a low voltage is applied to each of the transfer electrodes V1 to V6, the electric potential under the corresponding transfer electrode becomes shallow to form a potential barrier.

At time T0, by applying the high voltage to the transfer electrode V1 and by applying the low voltage to the transfer electrodes V2, V3, V4, V5 and V6, the electric potential under the transfer electrode V1 is deep, and the electric potential under the transfer electrodes V2 to V6 become shallow; and a charge pocket is formed under the transfer electrode V1 to store the signal electric-charge and barriers are made under the transfer electrodes V2 to V6 to prevent the signal being mixed. The packet size to store electric-charge is made of two electrodes.

Next, at time T1, the transfer electrode V2 becomes the high electric potential with maintaining the transfer electrode V1 in the high voltage having the charge packet formed under the electrode, and with maintaining the transfer electrodes V3 to V6 in the low electric potential having the barriers formed. Accordingly, since the electric potential under the electrode V2 becomes deep, the charge packet is formed with the two electrodes of V1 and V2, and the signal electric-charge previously stored under the transfer electrode V1 (at the time T0) also moves to the side of the transfer electrode V2.

At time T2, the transfer electrode V1 becomes the low electric potential with maintaining the transfer electrode V2 in the high voltage having the charge packet formed under the electrode, and with maintaining the transfer electrodes V3 to V6 in the low electric potential having the barriers formed. Accordingly, since the electric potential under the electrode V1 becomes shallow, all the signal electric-charge under the transfer electrode V1 moves to the position under the transfer electrode V2, where the signal electric-charge is stored.

At time T3, the transfer electrode V3 becomes the high electric potential with maintaining the transfer electrode V2 in the high voltage having the charge packet formed under the electrode, and with maintaining the transfer electrodes V4 to V6 in the low electric potential having the barriers formed. Accordingly, since the electric potential under the electrode V3 becomes deep, the charge packet is formed with the two electrodes of V2 and V3, and the signal electric-charge under the transfer electrode V2 also moves to the side of the transfer electrode V3.

At time T4, the transfer electrode V2 becomes the low electric potential with maintaining the transfer electrode V3 in the high voltage having the charge packet formed under the electrode, and with maintaining the transfer electrodes V4 to V6 in the low electric potential having the barriers formed. Accordingly, since the electric potential under the electrode V2 becomes shallow, all the signal electric-charge under the transfer electrode V2 moves to the position under the transfer electrode V3, where the signal electric-charge is stored.

At time T5, the transfer electrode V4 becomes the high electric potential with maintaining the transfer electrode V3 in the high voltage having the charge packet formed under the electrode, and with maintaining the transfer electrodes V1, V2, V5 and V6 in the low electric potential having the barriers formed. Accordingly, since the electric potential under the electrode V4 becomes deep, the charge packet is formed with the two electrodes of V3 and V4, and the signal electric-charge stored under the transfer electrode V3 also moves to the side of the transfer electrode V4.

At time T6, the transfer electrode V3 becomes the low electric potential with maintaining the transfer electrode V4 in the high voltage having the charge packet formed under the electrode, and with maintaining the transfer electrodes V1, V2, V5 and V6 in the low electric potential having the barriers formed. Accordingly, since the electric potential under the electrode V3 becomes shallow, all the signal electric-charges under the transfer electrode V3 moves to the position under the transfer electrode V4, where the signal electric-charge is stored.

The signal electric-charge under the transfer electrode V1 is transferred to the position below the transfer electrode V4 by the series of driving from the time T1 to the time T6. The period of time T1 to time T6 is approximately half a cycle of the vertical transfer pulses φV1 to φV4.

Subsequently, at time T7, the transfer electrode V5 becomes the high electric potential with maintaining the transfer electrode V4 in the high voltage having the charge packet formed under the electrode, and with maintaining the transfer electrodes V1, V2, V3 and V6 in the low electric potential having the barriers formed. Accordingly, since the electric potential under the electrode V5 becomes deep, the charge packet is formed with the two electrodes of V4 and V5, and the signal electric-charge under the transfer electrode V4 also moves to the side of the transfer electrode V5.

At time T8, the transfer electrode V4 becomes the low electric potential with maintaining the transfer electrode V5 in the high voltage having the charge packet formed under the electrode, and with maintaining the transfer electrodes V1, V2, V3 and V6 in the low electric potential having the barriers formed. Accordingly, since the electric potential under the electrode V4 becomes shallow, all the signal electric-charges under the transfer electrode V4 moves to the position under the transfer electrode V5, where the signal electric-charge is stored.

At time T9, the transfer electrode V6 becomes the low electric potential with maintaining the transfer electrode V5 in the high voltage having the charge packet formed under the electrode, and with maintaining the transfer electrodes V1 to V4 in the low electric potential having the barriers formed. Accordingly, since the electric potential under the electrode V6 becomes deep, the charge packet is formed with the two electrodes of V5 and V6, and the signal electric-charge under the transfer electrode V5 also moves to the side of the transfer electrode V6.

At time T10, the transfer electrode V5 becomes the low electric potential with maintaining the transfer electrode V6 in the high voltage having the charge packet formed under the electrode, and with maintaining the transfer electrodes V1 to V4 in the low electric potential having the barriers formed. Accordingly, since the electric potential under the electrode V5 becomes shallow, all the signal electric-charges under the transfer electrode V5 moves to the position under the transfer electrode V6, where the signal electric-charge is stored.

At time T11, the transfer electrode V1 becomes the low electric potential with maintaining the transfer electrode V6 in the high voltage having the charge packet formed under the electrode, and with maintaining the transfer electrodes V2 to V5 in the low electric potential having the barriers formed. Accordingly, since the electric potential under the electrode V1 becomes deep, the charge packet is formed with the two electrodes of V6 and V1, and the signal electric-charge under the transfer electrode V6 also moves to the side of the transfer electrode V1.

At time T12, the transfer electrode V6 becomes the low electric potential with maintaining the transfer electrode V1 in the high voltage having the charge packet formed under the electrode, and with maintaining the transfer electrodes V2 to V5 in the low electric potential having the barriers formed. Accordingly, since the electric potential under the electrode V6 becomes shallow, all the signal electric-charges under the transfer electrode V6 moves to the position under the transfer electrode V1, where the signal electric-charge is stored.

The signal electric-charge under the transfer electrode V4 is transferred to the position below the transfer electrode V1 by the series of driving from the time T7 to the time T12. The period of time from time T7 to time T12 is approximately half a cycle of the vertical transfer pulses φV1 to φV6.

Then, as understood from the above, the signal electric-charge stored under the transfer electrode V1 at time T0 is transferred by the series of driving from the time T0 to the time T12 to the position under the transfer electrode V1 which is away only by a pixel. Then, the electric-charge transfer at the time T6 is in the state of 180 degrees shifted (reverse phase) compared to that at the time T12 (equivalent to T0). In addition, between the time T2 and the time T6 or between the time T4 and T8, the electric-charge transfer is in the state of 180 degrees shifted to each other.

Therefore, according to the above, the electric-charge transfer for one electrode can be executed by the ⅙ cycle (60 degrees phase difference) of the six-phase drive, and the electric-charge transfer for two electrodes can be executed by the ⅓ cycle (120 degrees phase difference), and the electric-charge transfer for the three electrodes can be executed by the ½ cycle (180 degrees phase difference) and the electric-charge transfer for six electrodes can be executed by one cycle.

In other words, in this drive method, with respect to each dummy vertical CCD 132 of the odd column and the even column, the difference by three vertical transfer electrodes (three registers) is provided, so that even if the vertical transfer electrodes V1 to V6 are used in common for the odd column and the even column, the state of the signal electric-charge of the phases having 180 degrees difference reaching the electric-charge detection unit 210 can be obtained.

Further, when the signal electric-charge of the odd column reaches the floating diffusion FD through one cycle (T1 to T12 shown in FIG. 6) of the vertical transfer pulses of φV1 to φV6, the signal electric-charge of the even column has not reached yet. On the contrary, when the signal electric-charge of the even column reaches the floating diffusion FD, the signal electric-charge of the odd column has not reached yet.

Therefore, in the state in which a selective gate voltage VOG is fixed, the read-out of the odd column is completed by vertically transferring the signal electric-charge from time T1 to T6 and by scanning horizontally. Next, after a reset gate pulse φRG is turned on and the floating diffusion FD is cleared, the read-out of the even column is completed by vertically transferring the signal electric-charge in the rest of the time from T7 to T12 and by scanning horizontally. By repeating such processing, the pixel signal in time series corresponding to the signal electric-charge of one screen (the whole of the image pick-up area 100) can be output from the output signal wire 290.

Further, as assumed from the above, in order to obtain the state in which electric-charge transfer has 180 degrees difference (reverse phase), vertical transfer electrodes V1 to V6 may not be shared, but the vertical transfer electrodes V1 to V6 which can be driven independently for each of the odd column and the even column may be used. In this case, the dummy vertical CCD 132 becomes unnecessary and vertical CCD may have the same length. However, it is necessary to make the layout (formation) of the vertical transfer electrodes V1 to V6 for the odd column and the even column independently. Therefore, the patterning on the vertical transfer electrode side becomes difficult.

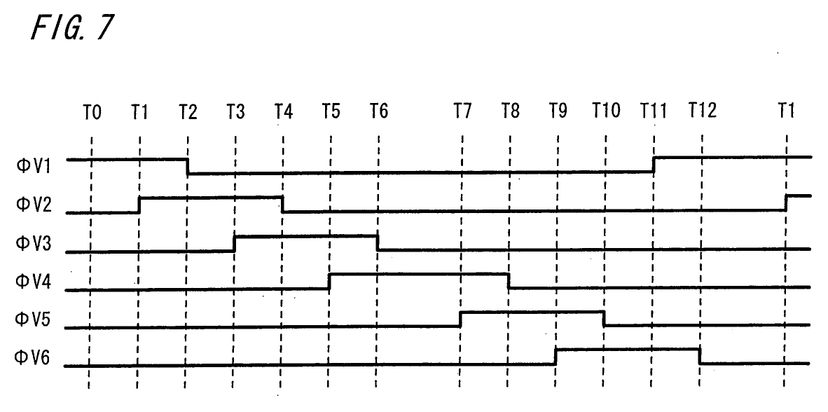

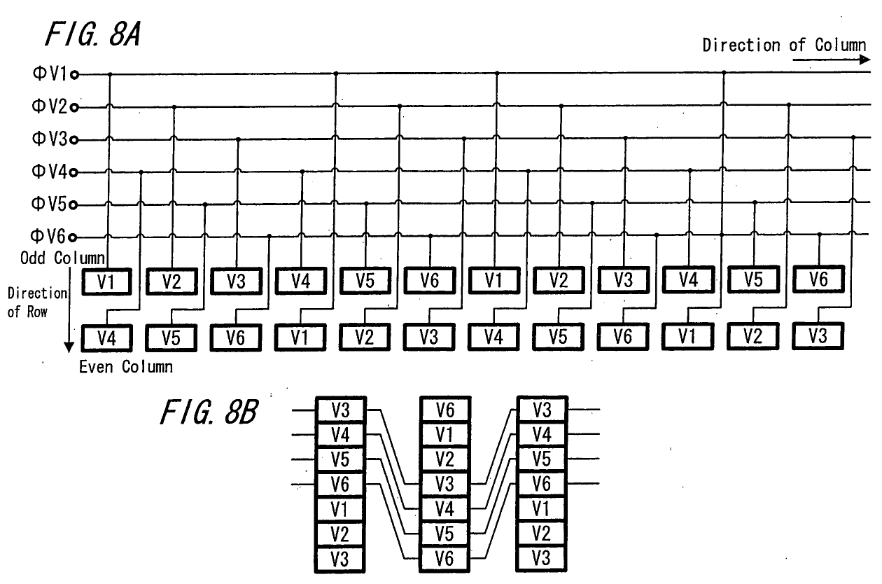

FIGS. 7 and 8 are the drawings explaining an example in which the arrangement of the vertical transfer electrodes V1 to V6 is changed to solve the above problem and to make electric-charge transfer have a reverse phase. In this example, the vertical transfer electrodes V1 to V4 are shared and the dummy vertical CCD 132 is not provided, and the phase of electric-charge transfer is made to become a reverse phase when the signal electric-charge of the photo-conductive units 120 in the same row reaches the electric-charge detection unit 210. As shown in FIG. 8A, with respect to the odd column and the even column the arrangement of the vertical transfer electrodes V1 to V6 in the same row is made to have a reverse phase. In order to obtain such patterning, the patterning as shown in FIG. 8B of schematic zigzag-shape may be performed.

With the above configuration, the signal electric-charge can be transferred with reverse phase to the side of the floating diffusion FD, with sharing the various electrodes such as the vertical transfer electrodes V1 to V6, the electrode used for the selective gate VOG and others, using the common vertical transfer pulses φV1 to φV6 for the odd column and for the even column, and without providing the dummy vertical CCD 132. Namely, when the signal electric-charge of the odd column reaches the floating diffusion FD, the signal electric-charge of the even column has not reached yet. On the contrary, when the signal electric-charge of the even column reaches the floating diffusion FD, the signal electric-charge of the odd column has not reached yet.

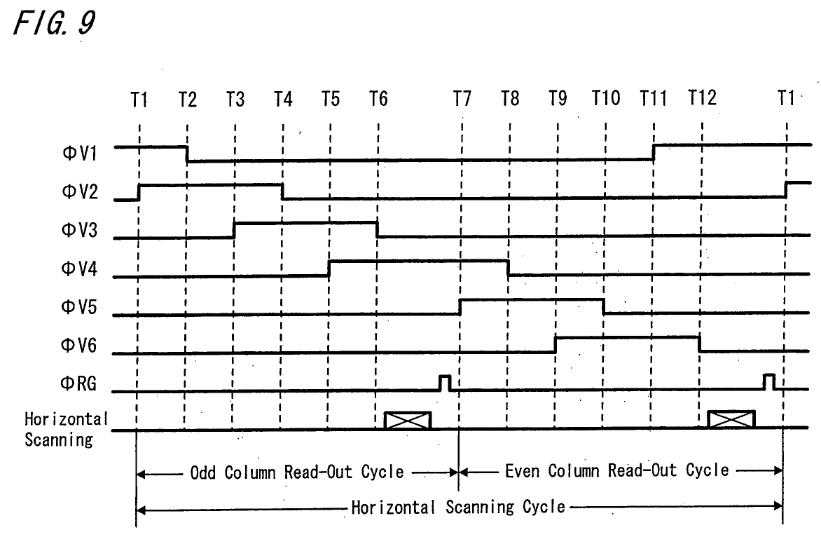

FIG. 9 is a timing chart that explains the vertical transfer and read-out in the horizontal direction in the case where the CCD solid state image sensor of the first embodiment is used and that shows the whole operation from electric-charge transfer in the vertical direction until obtaining the pixel signal of time series from the output signal wire 290 in one horizontal scanning cycle.

As described above, the register (charge packet) corresponding to each of the transfer electrodes V1 to V6 of the vertical CCD and the dummy vertical CCD 132 is driven by the completely the same vertical transfer pulses φV1 to φV6. Further, the reset gate pulse φRG is used accordingly for the odd column and the even column in common, because the corresponding electrode is formed in common.

In the period of each read-out cycle of the odd column or of the even column in one horizontal cycle shown in FIG. 9, by driving the vertical transfer pulses φV1 to φV6 with the timing shown in the drawing, each signal electric-charge of the odd column and even column which is stored in the register below the vertical transfer pulses φV1 to φV6 is sequentially transferred in parallel (at the same time) to the side of the dummy vertical CCD 132. The electric-charge of each column which has been transferred to the register corresponding to the pixel of the final stage of the vertical CCD 130 is transferred to the floating diffusion FD of the electric-charge detection unit 210 through the dummy vertical CCD 132.

Accordingly, the electric-potential of the floating diffusion FD changes, and that electric-potential is detected through a source follower type amplifier not shown in the drawing. After the signal electric-charge is detected, a reset gate wire (electrode) RG is turned on by the reset gate pulse φRG, and the electric-potential of the floating diffusion FD is reset to the voltage V_{RD} of reset drain which is an N+ region.

Hereupon, the register (charge packet) of the odd column has the three-stage difference from that of the even column in the dummy vertical CCD 132, and the signal electric-charge is made to reach the floating diffusion FD with 180 degrees difference (inverse phase) in one cycle of the vertical transfer pulses φV1 to φV6 (T1 to t12 shown in the drawing). Therefore, when the signal electric-charge of the odd column reaches the floating diffusion FD, the signal electric-charge of the even column has not reached yet. On the contrary, when the signal electric-charge of the even column reaches the floating diffusion FD, the signal electric-charge of the odd column has not reached yet.

Therefore, when vertical transfer pulses φV1 to φV6 are driven by the illustrated timing at the timings of T1 to T12, at time T6 in the odd column read-out cycle (T1 to T7) of the first half, the signal electric-charge of the odd columns of A, C, E . . . is transferred to the floating diffusion FD; is converted to the voltage signal in the electric-charge detection unit 210 (the electric-charge is read out); and is input to the column selection unit 270 through the band-limit unit 230 and the CDS processing unit 250. During the time between T6 and T7, an image signal of the time series corresponding to the signal electric-charge of the odd columns such as columns A, C, E . . . in one line is output to the output signal wire 290 by the control of the column selection pulse SP (n) over the column selection unit 270, that is, by the horizontal scanning by means of the column selection pulse generator 280.

Here, because the length of the odd columns A, C, D . . . is different from that of the dummy vertical CCD 132 of the even columns B, D, F . . . such that the phase of electric-charge transfer rotates 180 degrees, so that at the time T6 when the electric-charge of the odd columns A, C, E . . . reaches the floating diffusion FD in the odd column read-out cycle of the T1 to T7, the signal electric-charge of even columns B, D, F . . . has not reached the floating diffusion FD.

After the horizontal scanning by the column selection pulse generator 280 until the time T7, the switch of the reset gate RG is turned on by the reset gate pulse φRG, and after the electric potential of the floating diffusion FD is returned to the reset level and the floating diffusion FD is cleared, the switch of the reset gate is turned off.

Then, when the vertical transfer pulses φV1 to φV6 are driven by the illustrated timing in each of the timings T7 to T1 of the even column read-out cycle of the second half, similarly to the above described operation of columns A, C, E . . . the signal electric-charge of even columns B, D, F . . . start to be transferred, and reaches the floating diffusion FD at the time T12. At this time, the signal electric-charge of the odd column has not reached the floating diffusion FD yet, because the phase of the electric-charge transfer thereof has the 180-degree difference.

After transferred to the floating diffusion FD, the signal electric-charge of the even column is converted into the voltage signal in the electric-charge detection unit 210 (the signal electric-charge is read out), and then is input to the column selection unit 270 through the band-limit unit 230 and the CDS processing unit 250. During the time between T12 and T1 of the next horizontal scanning cycle, an image signal of the time series corresponding to the signal electric-charge of the odd columns such as A, C, E . . . , in one line is output to the output signal wire 290 by the control of the column selection pulse SP (n) over the column selection unit 270, that is, by the horizontal scanning by the column selection pulse generator 280.

Therefore, as shown in the drawing, the processing of the output of the odd column image signal to the output signal wire 290 being completed and the output of the even column image signal to the output signal wire 290 being completed is repeatedly performed, so that the pixel signal of time series corresponding to the signal electric-charge for one horizontal scanning cycle can be output from the output signal wire 290. Then, with repeating sequentially the processing with respect to one horizontal scanning cycle, the image signal corresponding to the signal electric-charges for one screen can be output from the output signal wire 290.

As described above, since a plurality of adjacent columns (an odd column and even column in the above embodiment) of the vertical CCDs are assigned as a group to one electric-charge detection unit, in which the number of stages included in each column is changed, each signal electric-charge of the odd column and of the even column can be sequentially read out to the side of the electric-charge detection unit in time series. Then, when the floating diffusion FD is for example used as the electric-charge detection unit 210, the number of wiring connected to the selective gate VOG can be reduced by providing the selective gate VOG for the plurality of columns (an odd column and even column in the above embodiment) in common, and the area can be used effectively, for example, in view of incorporating the CDS processing unit 250, and others. Further, the number of circuits existing subsequently to an electric-charge detection unit 210 is required to be the same number as the electric charge detection units 210, and the number can be reduced because a plurality of columns (an odd column and even column in the above embodiment) are made into one group, so that the electric power consumption can be reduced.

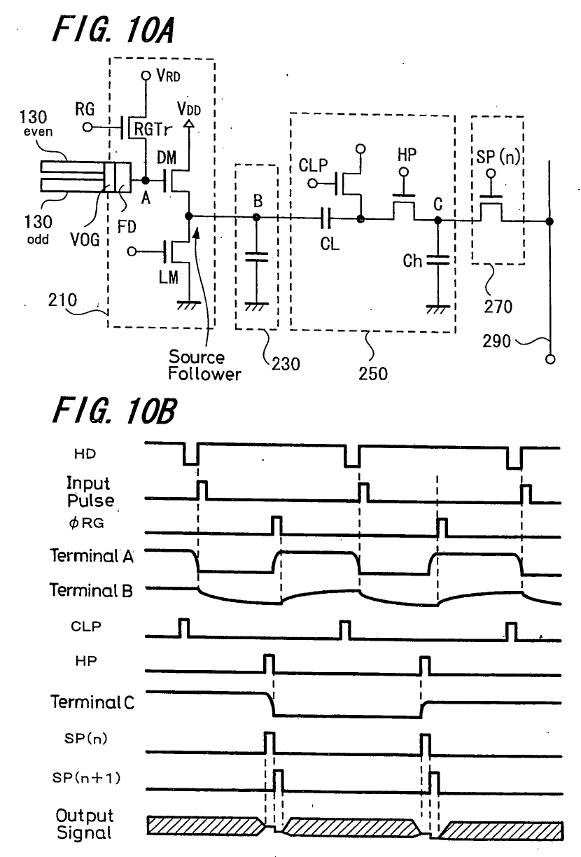

FIGS. 10A and 10B are diagrams showing a first example of the configuration for one unit of operation with respect to the electric-charge detection unit 210, the band-limit unit 230, the CDS processing unit 250 and the column selection unit 270 in the read-out processing unit 200. FIG. 10A is a circuit diagram and FIG. 10B is a timing chart that explains the operation thereof.

In this read-out processing unit 200, the electric-charge detection unit 210 constitutes a prior stage output unit (pre-amplifier) incorporated in the CCD solid state image sensor 10; has a source follower (current amplifier circuit) structure having a drive MOS transistor (DM: Drive MOS) DM and a load MOS transistor (LM; Load MOS) LM; and includes a MOS transistor having a reset gate terminal which is controlled based on the reset gate pulse φRG and a function of converting the signal electric-charge from the vertical CCD 130 into the voltage signal. Note that though one stage source follower is used in the diagram, plural stages of source followers may be used.

The gate of the drive MOS transistor DM is connected to the floating diffusion FD in which the signal electric-charge supplied from vertical CCD 130 through the selective gate VOG is accumulated and a source of the MOS transistor RGTr used for the reset gate RG is connected to the reset drain power source VRD to discharge the signal electric-charge. The floating diffusion FD is connected to the vertical CCDs 130 of two columns of an odd column (odd) and an even column (even) to constitute the floating diffusion amplifier FDA. The reset drain power source VRD can be shared with the power source V_{DD}.

In the electric-charge detection unit 210, a predetermined selective gate voltage V_{OG} is applied to the selective gate VOG and the reset gate pulse φRG is applied to the reset gate wire RG in the signal electric-charge detection cycle. Then, the signal electric-charge accumulated in the floating diffusion FD is converted into the signal voltage and is output as the pixel signal through the output circuit of the source follower structure including the drive MOS transistor DM and load MOS transistor LM.

Then, the signal electric-charge stored immediately before a certain time in the gate capacity of the first stage source follower is reset when a pulse is applied to the reset gate wire RG. At this time, a terminal A becomes a reset electric-potential. With respect to a point B, the reset electric-potential is fixed after the delay by a time constant which is determined by the output impedance of the first stage source follower and a band-limit capacity Cout. When the reset electric-potential is fixed at the point B, a pulse is input to a clamp pulse CLP and the reset electric-potential is clamped.

Next, the signal electric-charge is input to the terminal A by the input pulse. Then, the electric-potential drops to the extent of the signal electric-charge at the terminal A. Further, at the point B, similarly to the time when resetting, the signal electric-potential is fixed after the delay by the time constant. At this time, a pulse is applied to a hold pulse HP, and the electric-potential at that time is stored in a point C. The electric-potential of the difference between the signal electric-potential and the reset electric-potential is stored in the point C.

Subsequently, the image signal is output to the output signal wire 290 by supplying a column selection pulse SP (n) to a column selection unit 270 by a column selection pulse generator 280. In this operation, a period of time when detecting the signal electric-potential and a period of time when detecting the reset electric-potential are made equal. This is because when the difference between the signal electric-potential and the reset electric-potential is obtained in the CDS processing unit 250 at the subsequent stage, two electric potentials are required to be restricted by the same bandwidth to have the noise component of the same level. In other words, it is because a noise component becomes large in the signal in which the difference is obtained, even if one of the two signals has a low noise component.

With the above configuration, since the bandwidth can be restricted by a low pass filter composed of the output impedance of the first stage source follower and the band-limit capacity Cout, the noise component contained in the output signal can be made small. Further, the read-out processing unit 200 incorporates the CDS processing unit 250 which detects the difference (difference in the output) between the reset electric-potential of the period virtually without a signal electric-charge and the signal electric-potential of the period virtually with a signal electric-charge, so that at the same time the reset noise which occurs in the dispersion of the electric-potential when the electric-charge of immediately before the time is reset and a fixed pattern noise (FPN) can also be suppressed using the CDS (correlation double samplings) function; and a signal with excellent S/N can be obtained. Note that the density unevenness caused by the difference of the conversion gain in the electric-charge detection unit 210 becomes comparatively high frequency, so that the density unevenness on the screen can be invisible not to cause a problem.

Moreover, similarly to the electric-charge detection unit 210, one band-limit unit 230 and one CDS processing unit 250 are only required to be provided with respect to the plurality of columns (two columns in this embodiment) of the vertical CCD 130, which contributes to the reduction of the sensor area and electric power consumption. In addition, since a CDS circuit need not have a structure of being attached to the outside, peripheral circuits can also be reduced.

Though the electric-charge detection unit 210 and others are provided for every two vertical CCDs 130 in the above configuration, needless to say, one electric-charge detection unit 210, one CDS processing unit 250 and others may be provided for every three or more vertical CCDs 130, and may be used with further time sharing. With this configuration, since the total number of the electric-charge detection units 210, the CDS processing units 250 and other units can further be reduced, the sensor area and the electric power consumption can be reduced all the more.

Further, a selective gate VOG can be omitted in the configuration of FIG. 2.

The electric-charge detection unit 210 shown in FIG. 10A is constructed using the floating diffusion; however, the configuration is not limited thereto and, for example, a floating gate (refer to; ISSCC Digest of Technical Papers, 197391, pp. 154-155) can be used. When the floating gate is used, the signal not having a direct current can be obtained, so that the operation point can easily be set at around half the power supply voltage in the next stage amplifier.

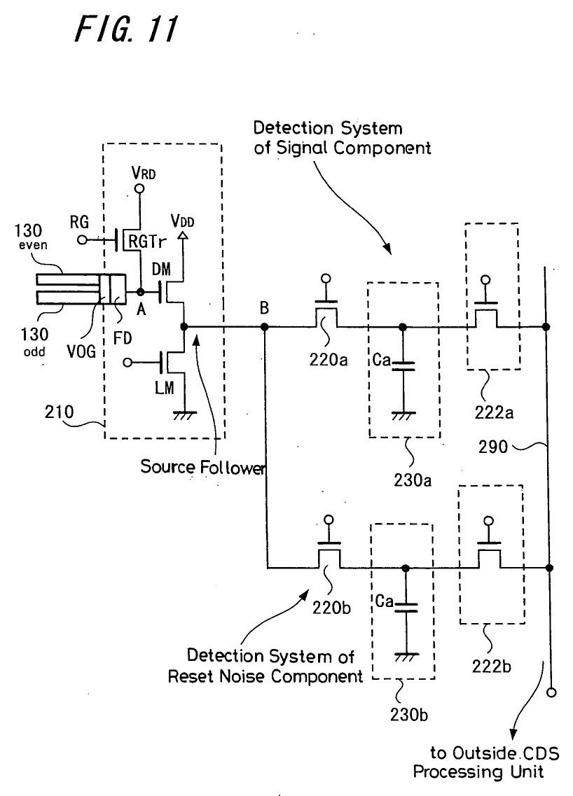

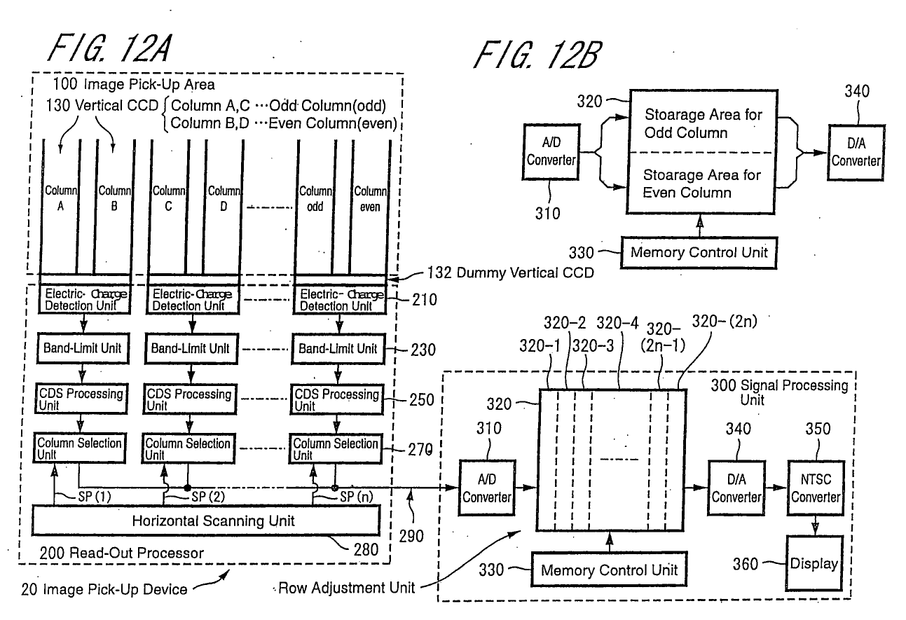

FIG. 11 is a circuit diagram showing a second example of the configuration for one unit of operation with respect to the electric-charge detection unit 210, the band-limit unit 230, the CDS processing unit 250 and the column selection unit 270 in the read-out processing unit 200. In the second example of the configuration, the circuit subsequent to the electric-charge detection unit 210 is divided into two systems such as a signal component detection system and a reset noise component detection system to perform processing. In other words, this configuration is characterized in that a first band-limit unit 230a having band-limit capacity Ca and a second band-limit unit 230b having a band-limit capacity Cb are used to separately restrict the signal component and the reset noise component.

A signal component selection MOS transistor 220a is arranged between the electric-charge detection unit 210 and the band-limit unit 230a of the signal component detection system, and the band-limit unit 230a has a band-limit capacity Ca used for the signal component. A column selection MOS transistor 222a used for the signal component is arranged between the band-limit unit 230a and the output signal wire 290. Further, a reset noise component selection MOS transistor 220b is arranged between the electric-charge detection unit 210 and the band-limit unit 230b of the reset noise component detection system, and the band-limit unit 230b has a band-limit capacity used for the reset noise component. A column selection MOS transistor 222b used for the reset noise component is arranged between the band-limit unit 230b and the output signal wire 290. The electric-charge detection unit 210 and the vicinity thereof are similar to the first example of the configuration.

In the operation of the second configuration, when the signal component is being input into the terminal A, the signal component selection MOS transistor 220a is turned on; and when the reset noise component is being input into the terminal A, the reset noise component selection MOS transistor 220b is turned on. Then, the signal component accumulates in the band-limit capacity Ca used for the signal component, and the reset noise component accumulates in the band-limit capacity Cb used for the reset noise component. Further, when a column is selected, the column selection MOS transistor 222b for the reset noise component and the column selection MOS transistor 222a for the signal component are turned on sequentially. As a result, the reset noise component and the signal component are sequentially output to the output signal wire 290 and are input into the CDS circuit attached on the outside.

The noise which occurs in the CDS circuit depends on a clamp capacity CL and a hold capacity Ch shown in FIG. 10. If each capacity is enlarged as much as possible, the noise which occurs becomes small. In the second example of the configuration, a reset noise component and a signal component are sequentially output, so that the CDS processing can be performed on the outside. Since the CDS processing is performed on the outside, each value of the clamp capacity CL and the hold capacity Ch can be enlarged to make the noise which occurs in the CDS circuit small.

FIGS. 12A and 12B are block diagrams showing an example of the whole configuration of the image pick-up device 20 including the signal processing circuit connected subsequently to the read-out processing unit 200. Hereupon, the system block diagram to reproduce a picture from the image pick-up device 20 using the CCD solid state image sensor 40 of the first embodiment is shown.

A signal processing unit 300 is connected to the output signal wire 290 and includes: an A/D converter 310 which converts an analogue image signal into digital image data, a picture memory unit (field memory) 320 which stores the digital image data by the unit of one screen, and a memory control unit 330 which controls the write-in and read-out of the data of the picture memory unit 320. A row adjustment unit according to the present invention is composed of the picture memory unit 320 and the memory control unit 330. Specifically, the function as the row adjustment unit, which obtains the image signal aligned in order in the horizontal direction, is obtained by rearranging each pixel signal of each image signal of the odd column and even column, which is output from the read-out processing unit 200 in the direction of the row corresponding to the arrangement of the row and the column.

The signal processing unit 300 further includes: a D/A converter 340 which converts the video data read out from the picture memory unit 320 into the analogue signal, an NTSC converter 350 which generates based on the video signal converted to the analogue signal by the D/A converter 340 an NTSC signal that is an example of the broadcast format, and a display 360 which displays the visible picture based on the NTSC signal output from the NTSC converter 350.

In this configuration, the signal electric-charge converted by the photo-electric conversion in the photo-conductive unit 120 is respectively read out to the corresponding vertical CCD 130. The signal electric-charge read out to the vertical CCD 130 is sequentially transferred in parallel to the electric-charge detection unit 210 through the floating diffusion in the time sharing with a plurality of adjacent lines as a group.

The signal electric-charge of each column transferred to the electric-charge detection unit 210 is converted into the voltage signal in the electric-charge detection unit 210; an offset noise and a fixed pattern noise are controlled by a CDS processing unit 250; and the image signal corresponding to each photo-conductive unit 120 in the image pick-up area 100 is output in time series from the output signal wire 290 by the horizontal scanning function of the column selection pulse generator 280 with respect to the column selection unit 270.

The image signal corresponding to each photo-conductive unit 120, which is output in time series from the output signal wire 290, is input into the signal processing unit 300, and the A/D conversion is performed to convert the signal by the A/D converter 310 and the signal is stored in the picture memory unit 320. A memory control unit 330 is connected to the picture memory unit 320, and the address setting of memory area and the control over the order of the read-out and so on are performed.

In the case of the CCD solid state image sensor 40 of the first embodiment, each signal electric-charge of the odd column and the even column of the vertical CCDs 130 is transferred to the read-out processing unit 200 in the time sharing, and after converted into the voltage signal, the image signal corresponding to each photo-conductive unit 120 in the image pick-up area 100 is made to be in time series by a horizontal scanning function of the column selection pulse generator 280 with respect to the column selection unit 270. Therefore, in every horizontal scanning cycle, in the horizontal scanning cycle of the first half, the image signal in time series for the odd column is only output first, and subsequently, in the horizontal scanning cycle of the last half, the image signal in time series for the even column is only output.

The image signal in which the odd column and the even column are output in the time sharing is digitized and sent to the side of the picture memory unit 320, and the memory control unit 330 sets the address of the picture memory unit 320 at the read-in time to correspond to the pixel position of the image pick-up area 100, so that the picked-up picture information in the image pick-up area 100 is made to have the same arrangement as the picture information in the picture memory unit 320.

Accordingly, the picture data corresponding to the signal electric-charge in the odd column in the vertical CCD 130 is stored in, for example, storage areas 320-1 to 320-(2n-1), and the picture data corresponding to the signal electric-charge in the even column in the vertical CCD 130 is stored in storage areas 320-2 to 320-(2n).

When the picture is reproduced, the picture data is sequentially read out from the storage areas 320-1 to 320-2n within the picture memory unit 320 as the serial data, and is displayed in a display 360 through the D/A converter 340 and the NTSC converter 350.

It should be noted that, in the above described example, the write-in position at the time of storing the data in the picture memory unit 320 is controlled by the memory control unit 330 so that the image picture information in the image pick-up area 100 and the picture information of the picture memory unit 320 have the same arrangement; however, the control can be performed at the read-out time instead of the write-in time. Specifically, as shown first in FIG. 12B, in the schematic view of the storage area of the picture memory unit 320, the storage area of the picture memory unit 320 is divided into the odd column area and the even column area, and the input data from the A/D converter 310 with respect to the odd column and the even column are stored sequentially in each storage area at the write-in time in order of data input. Then, at the read-out time the data of the odd column and of the even column A, B, C, D is alternately read out in each horizontal scanning cycle from the divided odd column area and the even column area, and is supplied to the D/A converter 340. Accordingly, the image picture information in the image pick-up area 100 and the picture on the display 360 can be made to have the same arrangement.

Further, although not shown in the drawings, instead of using a field memory as the picture memory unit 320, when with respect to each of the odd column and the even column a shift register (FIFO memory) having stages corresponding to the pixel number of half a line and a selection circuit to switch the shift register are used, data can be converted into the signal in time series of one horizontal line which is arranged in order of image picture information in the image pick-up area 100 (data can be rearranged to be aligned in order in the horizontal direction).

As described-above, according to the image pick-up device 20 of the first embodiment, the problem in which the clock frequency of a horizontal CCD reaches a limit when the pixel number of the CCD solid state image sensor increases can be solved without using horizontal CCD, such that signal electric-charge is transferred to the electric-charge detection unit (in the above embodiment, to an amplifier FDA using the floating diffusion) in the time sharing with a plurality of vertical CCDs as one group and is converted into the voltage signal in the electric-charge detection unit, and after that, the voltage signal in the vertical line is sequentially selected in the horizontal direction and is read out. The rearrangement of the data series by reading out a vertical line in the time sharing can be performed with a comparatively simple circuit, which can avoid a problem.

In addition, although the time sharing is employed, the sensitivity decline per pixel caused by the high density pixels can be complemented using the signal of adjacent pixels (or of the same color pixel positioned away by two pixels), because the signal electric-charge can be read out per vertical CCD.

Further, when a plurality of columns of the vertical CCDs, are connected to the electric-charge detection unit (in the above embodiment the floating diffusion amplifier FDA) as a group, the length of the vertical CCD, namely, the number of stages of the register (packet) defined by the vertical transfer electrode is changed with respect to the column, and the phase of electric-charge transfer when reaching the electric-charge detection unit is made invert, so that even if a vertical transfer electrode is shared, signal electric-charge can be read out to the electric-charge detection unit using one selective gate instead of using a plurality thereof (in the above example two) for the selection of the column CCD. As a result, the number of wiring around the electric-charge detection unit can be reduced, and the area can be used efficiently in view of incorporating the CDS circuit and other circuits with respect to the miniaturization of the solid state image sensor.

Further, although a time sharing is employed, since the electric-charge detection unit is provided virtually for each vertical CCD, only signals of several times (the same number as the columns which one electric-charge detection unit takes charge) are input to the electric charge detection unit in one horizontal scanning cycle and the frequency bandwidth of the signal becomes considerably small. Hence, the frequency bandwidth of the amplifier which constitutes the electric-charge detection unit can be restricted using the low pass filter. As a result, the band of the heat noise which occurs in the transistor at the same time can be restricted and a noise component can be made small. Further, since the signal bandwidth can be lowered, a noise bandwidth can be made narrow accordingly by the band-limit unit and the picture having an excellent S/N ratio can be obtained.

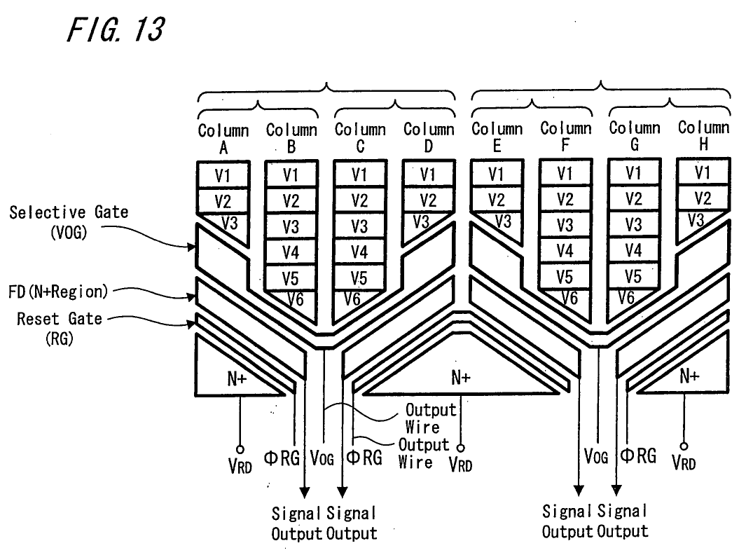

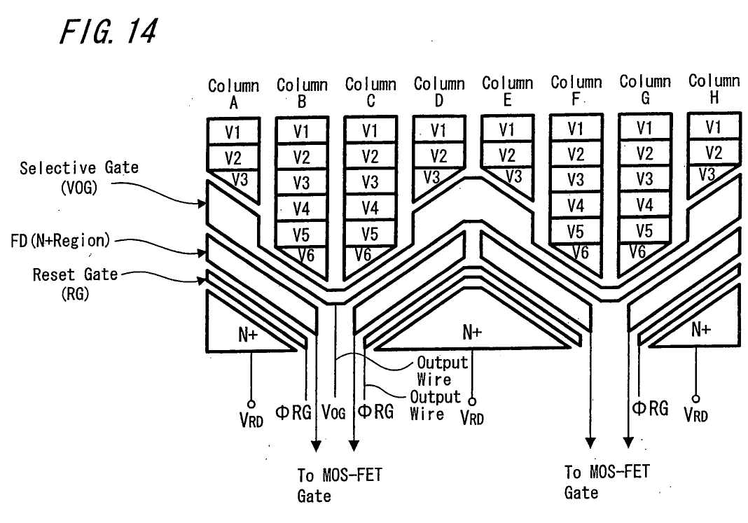

FIGS. 13 and 14 are drawings which explain modified examples of the CCD solid state image sensor 40 of the first embodiment and are schematic plan views showing the vicinity of the boundary portion of the vertical CCD 130 and the read-out processing unit 200. Hereupon, in the first modified example shown in FIG. 13 two sets of adjacent columns further become one group, in which the arrangement of the number of stages of the dummy vertical CCDs 132 is made to alternate with respect to the two sets, the electrode for the adjacent selective gate VOG is connected, and the output wire is shared.

That is, with the center line of two sets performed as the boundary, the number of stages of the dummy vertical CCD 132 is made to change sequentially corresponding to the distance from the center line. Further, in the first modified example shown in FIG. 13, an adjacent reset gate wire is connected to a center line of the different position from the center line of the above-mentioned two sets, and the output wire can be shared. According to the first modified example, the electrodes for the selective gate VOG and the reset gate are connected between adjacent sets, so that the number of output wires can further be reduced.

Further, in FIG. 13, for example, two sets of adjacent columns A and B and adjacent columns C and D are made one group, and two sets of adjacent columns C and D and adjacent columns E and F are made one group; and the electrode for the selective gate VOG is connected between the columns B and C, and the reset gate wire is connected between the columns D and E. However, other grouping than the above can be employed.

For example, two sets of columns C and D and columns E and F may be made one group, respectively and an electrode for the selective gate VOG can be connected in the same way between the columns D, E. The second modified example shown in FIG. 14 is an example further developed from the above example, in which all the electrodes for the selective gate VOG are connected and the output wires of the selective gate can further be reduced. In this case, fundamentally the number of output wires is one; however, the problem of wire resistance occurs. Therefore, it is preferable that the position where the electrode and the output wire for the selective gate VOG are installed is practically decided in consideration of a balance between the wire resistance and the difficulty of wiring.

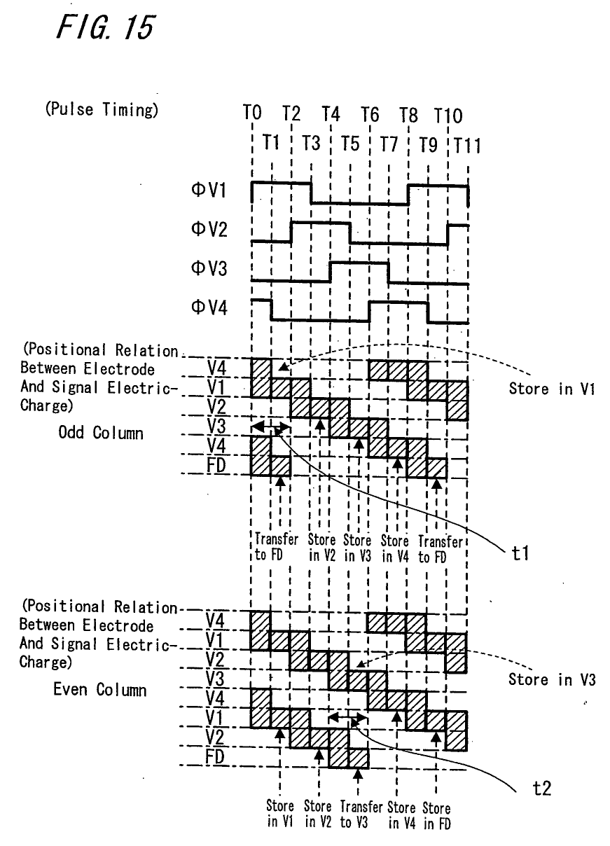

FIG. 15 is a diagram which explains a modified example of the timing chart when the vertical transfer pulses φV1 to φV4 of the four-phase drive is used and explains the positional relationship between the electrode and the signal electric-charge in the CCD solid state image sensor of the first embodiment. This modified example is characterized in that each of the vertical transfer pulses φV1 to φV4 is driven with 90 degrees shifted. The other configuration than the transfer electrodes V1 to V4 to which the vertical transfer pulses φV1 to φV4 for the four-phase drive are applied is the same as FIG. 1.

The following advantage can be obtained in this modified example, as understood from FIG. 15, with respect to the positional relationship between the electrode and the signal electric-charge. Specifically, with respect to the odd column, when the signal electric-charge of the packet V4 is transferred to the floating diffusion FD, the packet V2 of the relevant even column acts as a barrier during a period of time t1. Further, with respect to the even column, when the signal electric-charge of the packet V2 is transferred to the floating diffusion FD, the packet V4 of the relevant odd column acts as a barrier during a period of time t2.

In addition, in this modified example, when an accumulation packet size is small, the power supply voltage VDD is raised to obtain the depth of the voltage potential and the problem can be solved.

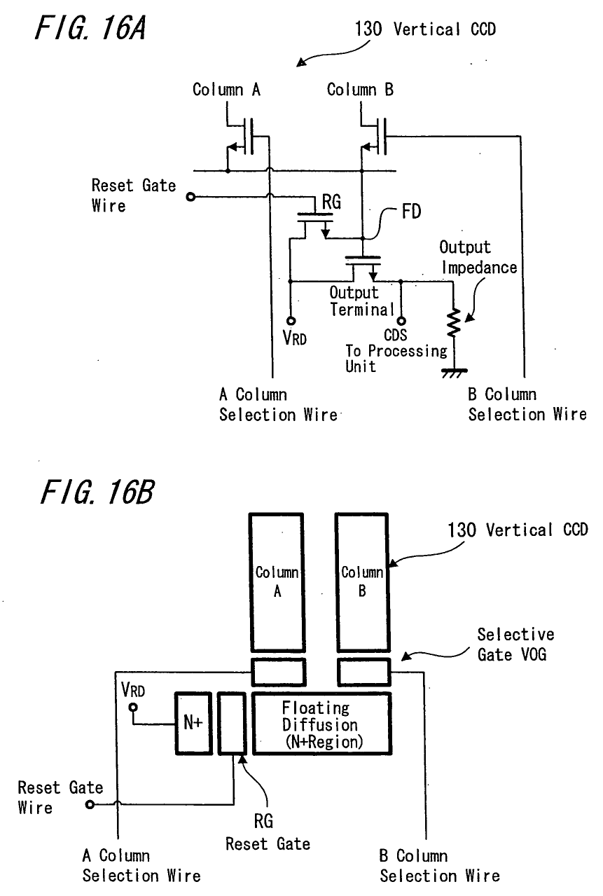

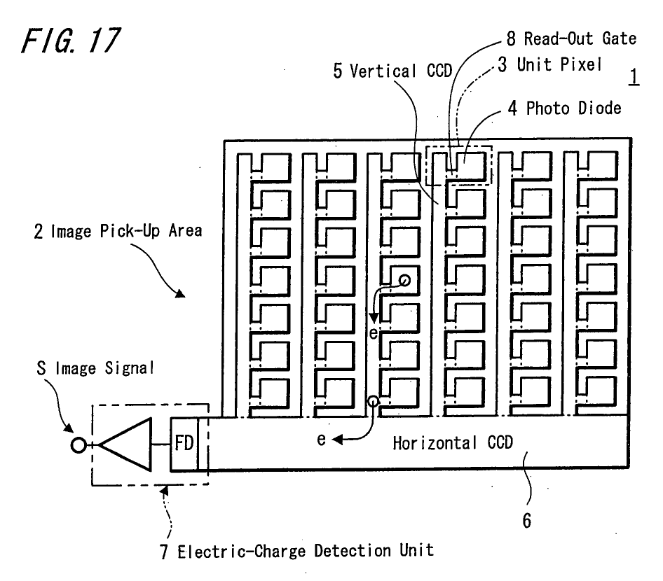

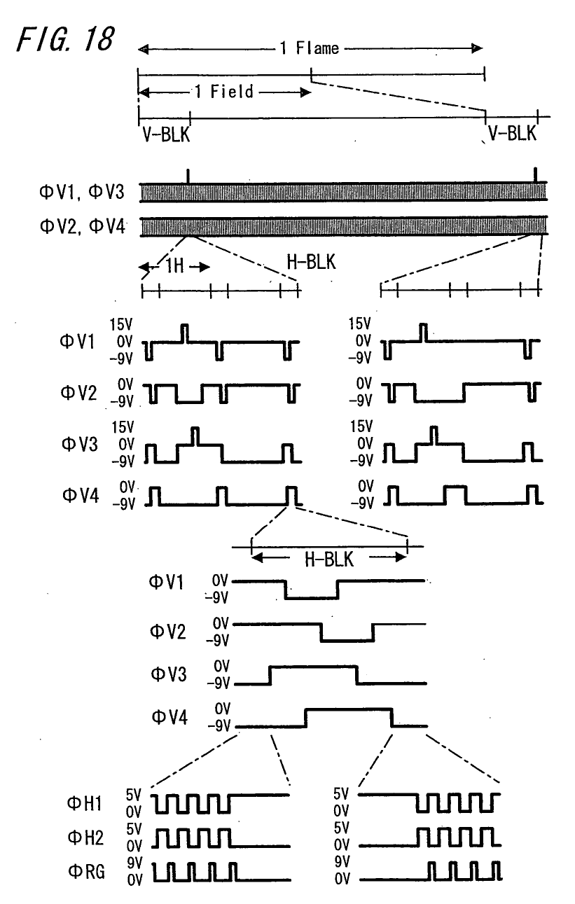

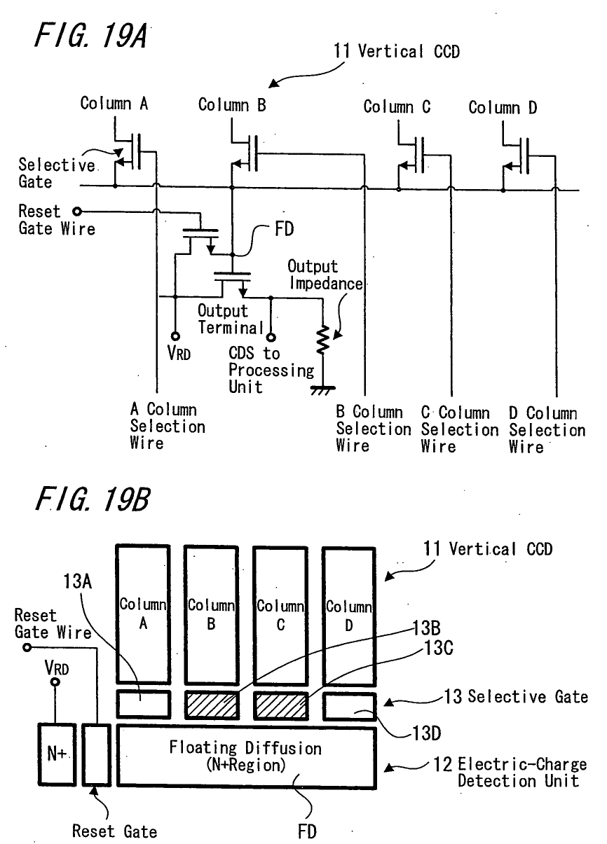

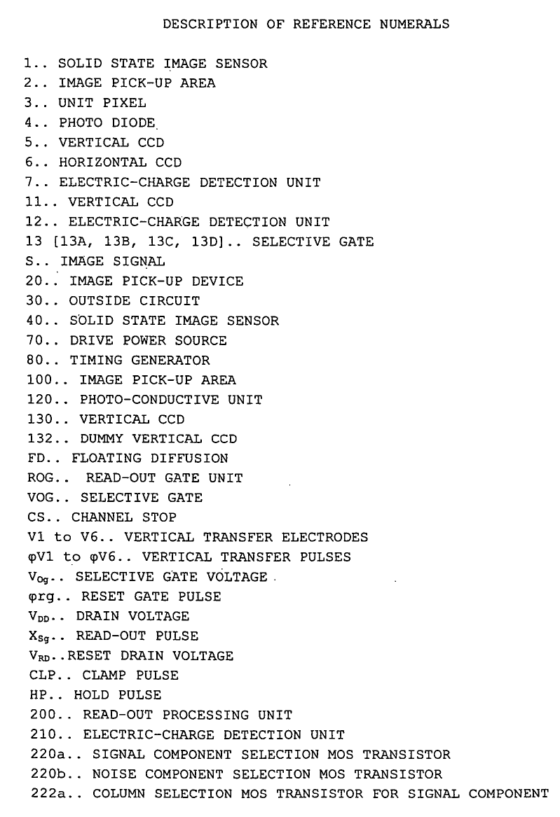

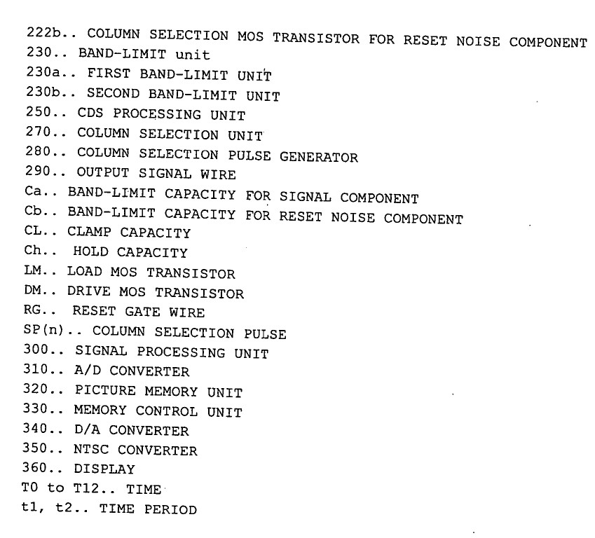

FIGS. 16A and 16B are diagrams which explain the CCD solid state image sensor 40 of the third embodiment. In this third embodiment, two adjacent vertical CCDs as one set are assigned to one electric-charge detection unit, which is common to the CCD solid state image sensor 40 of the first embodiment; however, in this embodiment the dummy vertical CCD 132 is not provided and the number of stages of the vertical CCDs remains the same. That is, two columns of vertical CCDs 130 are read out to the electric-charge detection unit 210 having the configuration of a floating diffusion FDA.

As shown in FIG. 16A, since the wiring of the selective gate VOG can be connected from the opposite side to each vertical CCD 130 with the floating diffusion in between, the restriction in the wiring decreases, compared with the configuration in which three or more as a group are assigned to one electric-charge detection unit 210 and the problem of the wiring space to the selective gate VOG in the center portion occurs, and problems can be avoided comparatively even in the actual pattern.

However, as shown in FIG. 16B, since the fact that the same number of wiring for the selective gate of the vertical CCD 130 is required as that of the vertical CCDs 130 remains unchanged, the ratio of occupying wiring to the area becomes larger than that of the first or the second embodiment.

The present invention has heretofore been explained using the embodiments; however, the scope of the present invention is not limited to the above-mentioned embodiments. Various changes or improvement can be added to the above embodiments within the range not departing from the spirit of the invention, and embodiments to which such changes or improvement is applied are also included in the scope of this invention.

Moreover, the invention described in appended claims is not limited by the above-described embodiments, and all the combinations of the characteristics being explained in the embodiments are not necessarily indispensable for the solution means of the invention. In the above-mentioned embodiments, invention of various stages is included and various kinds of invention can be extracted by appropriately combining the plurality of disclosed constituents. Even if some constituents are deleted from all constituents shown in the embodiments, the configuration from which those constituents are deleted can be extracted as an invention, as long as the effectiveness thereof can be obtained.

For example, though an example suitable for the six electrodes/six-phase drive and the four electrodes/four-phase drive is explained in the above-mentioned embodiments, the number of the vertical transfer electrodes and the relationship with the phases of the transfer pulses are not limited to ones having the above-mentioned timing. Moreover, not limited to two columns and three columns, more columns can be assigned to one electric-charge detection portion with respect to the relations with the transfer pulses.

In other words, when a plurality of adjacent columns are assigned to one electric-charge detection unit, the number of stages in the dummy vertical transfer unit (virtually the same as the vertical CCD), the arrangement of the vertical transfer electrodes and the timing of the vertical transfer pulses are changed such that each signal electric-charge in the same row reaches the electric-charge detection unit in a different phase to each other. The number of stages in the dummy vertical transfer portion and the arrangement of the vertical transfer electrodes are the same, and only a drive method may be different, in other words, only the timing of the transfer pulse can be different, which is also acceptable.

Moreover, although explanation is made in the above-mentioned embodiments using the CCD solid state image sensor of the inter-line transfer type, the present invention is not limited thereto and may be applied to a CCD solid state image sensor of the other transfer methods such as the frame inter-line transfer type, the full frame transfer type and the frame transfer type.

Furthermore, other types of electric-charge transfer unit than the above can also be used such that with respect to the vertical transfer portion, CCD is replaced with CSD (charge sweeped device), for example.

1. A solid state image sensor comprising:
a plurality of photo-conductive units which are arranged in each direction of the row and the column in the two-dimensional shape and which obtain a signal electric-charge by receiving light;
a column electric-charge transfer unit which transfers said signal electric-charge obtained by said photo-conductive unit in the direction of said column; and
an electric-charge detection unit which is provided for every plurality of said adjacent columns and which converts said signal electric-charge transferred by said column electric-charge transfer unit into a pixel signal; wherein
with respect to said plurality of adjacent columns, when said signal electric-charge obtained by said photo-conductive unit at the same position in the direction of said row reaches said electric-charge detection unit, a phase of the electric-charge transfer is made different.

2. A solid state image sensor comprising:
a plurality of photo conductive units which are arranged in each direction of the row and the column in the two-dimensional shape and which obtain a signal electric-charge by receiving light;
a column electric-charge transfer unit which transfers said signal electric-charge obtained by said photo conductive unit in the direction of said column;
an electric-charge detection unit which is provided for every plurality of said adjacent columns and which converts said signal electric-charge transferred by said column electric-charge transfer unit into a pixel signal; and
a dummy electric-charge transfer unit arranged between said column electric-charge transfer unit and said electric-charge detection unit, in which the number of stages of electric-charge transfer is different with respect to each of said plurality of columns.

3. The solid state image sensor according to claim 2, wherein
in the electric-charge transfer units of said plurality of adjacent columns, an electrode used for the vertical transfer drive is used in common.

4. The solid state image sensor according to claim 2, wherein
said electric-charge detection unit is provided for every two said adjacent columns.

5. The solid state image sensor according to claim 4, wherein
in said dummy electric-charge transfer unit, the number of stages of said electric-charge transfer is different to the extent that a phase of the electric-charge transfer becomes 180 degrees inverted between said two adjacent columns, when said signal electric-charge at the same position in the direction of said row is made to reach said electric-charge detection unit.

6. A solid state image sensor comprising:
a plurality of photo conductive units which are arranged in each direction of the row and the column in the two-dimensional shape and which obtain a signal electric-charge by receiving light;
a column electric-charge transfer unit which transfers said signal electric-charge obtained by said photo conductive unit in the direction of said column; and
an electric-charge detection unit provided for every plurality of said adjacent columns and which converts said signal electric-charge transferred by said column electric-charge transfer unit into a pixel signal, wherein
an electrode used for driving a vertical transfer is formed such that a phase of electric-charge transfer when said signal electric-charge obtained by said photo-conductive unit at the same position in the direction of said row reaches said electric-charge detection unit is different, when a common vertical transfer control signal is applied to said plurality of adjacent columns.

7. The solid state image sensor according to claim 1, wherein
said electric-charge detection unit includes a selective gate, which is shared with said plurality of adjacent columns, for reading out said signal electric-charge on the input side of said signal electric-charge.

8. The solid state image sensor according to claim 2, wherein
said electric-charge detection unit includes a selective gate, which is shared with said plurality of adjacent columns, for reading out said signal electric-charge on the input side of said signal electric-charge.

9. The solid state image sensor according to claim 6, wherein
said electric-charge detection unit includes a selective gate, which is shared with said plurality of adjacent columns, for reading out said signal electric-charge on the input side of said signal electric-charge.

10. The solid state image sensor according to claim 1, wherein
a wiring to said selective gate is shared with the wiring to said selective gate with respect to said electric-charge detection units of adjacent others.

11. The solid state image sensor according to claim 2, wherein
a wiring of said selective gate is shared with the wiring to said selective gate with respect to said electric-charge detection units of adjacent others.

12. The solid state image sensor according to claim 6, wherein
a wiring of said selective gate is shared with the wiring to said selective gate with respect to said electric-charge detection units of adjacent others.

13. A solid state image sensor comprising:
a plurality of photo-conductive units which are arranged in each direction of the row and the column in the two-dimensional shape and which obtain a signal electric-charge by receiving light;
a column electric-charge transfer unit which transfers said signal electric-charge obtained by said photo-conductive unit in the direction of said column; and
an electric-charge detection unit which is provided for every two of said columns and which converts said signal electric-charges transferred by said column electric-charge transfer unit into a pixel signal, wherein
said electric-charge detection unit includes a selective gate which is provided independently for each of said two adjacent columns for reading out said signal electric-charge on the input side of said signal electric-charge.

14. The solid state image sensor according to claim 1, wherein
each of said electric-charge detection units includes a reset gate in said electric-charge detection unit to be initialized after said signal electric-charge is converted into said pixel signal.

15. The solid state image sensor according to claim 2, wherein
each of said electric-charge detection units includes a reset gate in said electric-charge detection unit to be initialized after said signal electric-charge is converted into said pixel signal.

16. The solid state image sensor according to claim 6, wherein
each of said electric-charge detection units includes a reset gate in said electric-charge detection unit to be initialized after said signal electric-charge is converted into said pixel signal.

17. The solid state image sensor according to claim 13, wherein
each of said electric-charge detection units includes a reset gate in said electric-charge detection unit to be initialized after said signal electric-charge is converted into said pixel signal.

18. The solid state image sensor according to claim 1, wherein
a differential detection unit which detects the difference between the output without said signal electric-charge and the signal level with said signal electric-charge, of said pixel signal, is provided subsequently to said electric-charge detection unit.

19. The solid state image sensor according to claim 2, wherein
a differential detection unit which detects the difference between the output without said signal electric-charge and the signal level with said signal electric-charge, of said pixel signal, is provided subsequently to said electric-charge detection unit.

20. The solid state image sensor according to claim 6, wherein
a differential detection unit which detects the difference between the output without said signal electric-charge and the signal level with said signal electric-charge, of said pixel signal, is provided subsequently to said electric-charge detection unit.

21. The solid state image sensor according to claim 13, wherein
a differential detection unit which detects the difference between the output without said signal electric-charge and the signal level with said signal electric-charge, of said pixel signal, is provided subsequently to said electric-charge detection unit.

22. The solid state image sensor according to claim 1, further comprising:
a plurality of said electric-charge detection units with respect to said plurality of adjacent columns in the direction of said column with said plurality of columns as a group, and
a horizontal scanning unit subsequent to said plurality of electric-charge detection units, which sequentially selects and outputs said pixel signal that is output from each of said plurality of electric-charge detection units in time series in the direction of said row.

23. The solid state image sensor according to claim 2 further comprising:
a plurality of said electric-charge detection units with respect to said plurality of adjacent columns in the direction of said column with said plurality of columns as a group, and
a horizontal scanning unit subsequent to said plurality of electric-charge detection units, which sequentially selects and outputs said pixel signal that is output from each of said plurality of electric-charge detection units in time series in the direction of said row.

24. The solid state image sensor according to claim 6 further comprising:
a plurality of said electric-charge detection units with respect to said plurality of adjacent columns in the direction of said column with said plurality of columns as a group, and
a horizontal scanning unit subsequent to said plurality of electric-charge detection units, which sequentially selects and outputs said pixel signal that is output from each of said plurality of electric-charge detection units in time series in the direction of said row.

25. The solid state image sensor according to claim 13 further comprising:
a plurality of said electric-charge detection units with respect to said plurality of adjacent columns in the direction of said column with said plurality of columns as a group, and
a horizontal scanning unit subsequent to said plurality of electric-charge detection units, which sequentially selects and outputs said pixel signal that is output from each of said plurality of electric-charge detection units in time series in the direction of said row.

26. A drive method of a solid state image sensor, in which a pixel signal is obtained from a solid state image sensor that includes a column electric-charge transfer unit which transfers signal electric-charge obtained by photo-conductive units arranged in each direction of the row and the column in the two-dimensional shape in the direction of said column, and
an electric-charge detection unit which is provided for every plurality of said adjacent columns and which converts said signal electric-charge transferred by said column electric-charge transfer unit in the direction of said column into a pixel signal, wherein
said solid state image sensor is driven such that said pixel signal with respect to each of said plurality of said adjacent columns is output with a different phase when said signal electric-charge is transferred in the direction of said columns.

27. The drive method according to claim 26, wherein
said column electric-charge transfer unit is driven by six-phase drive.

28. The drive method according to claim 26, wherein
said electric-charge detection unit includes on the input side of said signal electric-charge
a selective gate for reading out said signal electric-charge, and
a reset gate for initializing after said signal electric-charge is converted into said pixel signal, and
said reset gate is made to turn on when said selective gate is off.

29. An image pick-up method to obtain an image signal using a solid state image sensor that includes a column electric-charge transfer unit which transfers the signal electric-charge obtained by the photo-conductive units arranged in each direction of the row and the column in the two-dimensional shape in the direction of said column, and
an electric-charge detection unit which is provided for every plurality of said adjacent columns and which converts said signal electric-charge transferred by said column electric-charge transfer unit in the direction of said column into a pixel signal, wherein
said pixel signal with respect to each of said plurality of said adjacent columns is obtained having a different phase in the transfer of said signal electric-charge in the direction of said columns;
the obtained pixel signal is sequentially selected in time series in the direction of said row, so that the image signal with respect to each of said different phases is obtained; and
after that, the image signal sequentially aligned in the direction of said row is obtained by rearranging said pixel signals of said image signal in the direction of said row in accordance with the order of said plurality of columns.

30. The drive method according to claim 29, wherein
said column electric-charge transfer unit is driven by six-phase drive.

31. An image pick-up device comprising:
a solid state image sensor, including:
a plurality of photo-conductive units which are arranged in each direction of the row and the column in the two-dimensional shape and which obtain a signal electric-charge by receiving light,
a column electric-charge transfer unit which transfers said signal electric-charge obtained by said photo-conductive unit in the direction of said column,
an electric-charge detection unit which is provided for every plurality of said columns and which converts said signal electric-charge transferred by said column electric-charge transfer unit into a pixel signal, and
a dummy electric-charge transfer unit arranged between said column electric-charge transfer unit and said electric-charge detection unit, in which the number of stages of electric-charge transfer is different with respect to each of said plurality of columns;
a horizontal scanning unit which obtains an image signal with respect to each of said different phases by sequentially selecting in time series in the direction of said row said pixel signals that are output from said solid state image sensor with the different phases in the transfer in the direction of said columns of said signal electric-charges; and
a row adjustment unit which obtains the image signal sequentially aligned in the direction of said row by rearranging said pixel signals of the image signal that are output from said horizontal scanning unit in the direction of said row in accordance with the order of said plurality of columns.
